(19) United States
(12) Patent Application Publication
(10) Pub. No.: US 2018/0346748 A1
(43) Pub. Date: Dec. 6, 2018

(54) FORMULATION FOR PRINTING ELECTRONIC DEVICE AND APPLICATION THEREOF IN ELECTRONIC DEVICE

(71) Applicant: GUANGZHOU CHINARAY OPTOELECTRONIC MATERIALS LTD., Guangzhou (CN)

(72) Inventors: Junyou PAN, Guangzhou (CN); Xi YANG, Guangzhou (CN); Hong HUANG, Guangzhou (CN)

(21) Appl. No.: 15/775,398

(22) PCT Filed: Sep. 14, 2016
(86) PCT No.: PCT/CN2016/000990

§ 371 Date: May 11, 2018

(30) Foreign Application Priority Data
Nov. 12, 2015 (CN) 201510770158.1

(51) Int. Cl. C09D 11/52; C09D 11/50; C09D 11/322; C09D 11/36; C09D 11/033; C09D 11/037; C09K 11/02; C09K 11/56; C09K 11/88; C09K 11/06; H01L 51/00

(52) U.S. Cl. CPC C09D 11/52; B82Y 20/00; C09D 11/322; C09D 11/36; C09D 11/033; C09D 11/037; C09K 11/025; C09K 11/565; C09K 11/883; C09K 11/06; H01L 51/0077; H01L 51/0067; H01L 51/0072; H01L 51/0085; H01L 51/0058; H01L 51/0059; H01L 51/0004; H01L 51/0005; H01L 51/0007; C09D 11/50

(57) ABSTRACT

The present disclosure discloses a formulation for printing electronic device comprising at least one functional material and at least one organic solvent based on alicyclic structure. In some embodiments, the viscosity of the organic solvent at 25° C. is from 1 cPs to 100 cPs; the surface tension at 25° C. is from 19 dyne/cm to 50 dyne/cm; and the boiling point is higher than 150° C. The present disclosure also relates a printing process of the formulation and an application of the formulation in an electronic device, in particular in an electroluminescent device. The present disclosure further relates to an electronic device prepared by using the formulation.

### CROSS-REFERENCE TO RELATED APPLICATIONS

The present application is the national phase of International Application No. PCT/CN2016/100164, filed on Sep. 26, 2016, which claims priority to Chinese Application No. 201510769470.9, filed on Nov. 12, 2015, both of which are incorporated herein by reference in their entireties.

### TECHNICAL FIELD

The disclosure relates to formulations for printing electronic device and applications thereof in electronic device, in particular in electroluminescent device.

### BACKGROUND ART

At present, organic light-emitting diode (OLED) as a new generation displays is manufactured by an evaporation method, resulting in a low material utilization, and the method requires a fine metal mask (FMM) that would increase the cost and decrease the yield. In order to solve the above problems, a printing technology for realizing a high-resolution full-color display attracts more and more attention. For example, a large-area functional material film can be manufactured by ink-jet printing at low cost. Compared with conventional semiconductor manufacture processes, the ink-jet printing has great advantages and potential due to a low energy consumption, a low water consumption and an environmentally friendly property thereof. Another new display technology is quantum dot light emitting diode (QLED), which cannot be manufactured by an evaporation method but only can be manufactured through printing. Therefore, in order to realize a printed display, it is necessary to make a breakthrough in printing inks and solve principal problems of related printing processes. Viscosity and surface tension are important parameters affecting the printing inks and the printing processes. A promising printing ink requires suitable viscosity and surface tension.

Organic semiconductor materials have gained widespread attention and made remarkable progress in electronic and optoelectronic devices due to solution processability thereof. The solution processability allows an organic functional material to form a film of such functional material in a device through certain coating and printing processes. Such technology can effectively reduce processing cost of electronic and optoelectronic devices and satisfy the need of a large area manufacture. Up to now, a plurality of companies have reported organic semiconductor material printing inks, for example: KATEEVA, INC disclosed an ink comprising a small molecular organic material based on an ester solvent applicable for printing an OLED (US2015044802A1); UNIVERSAL DISPLAY CORPORATION disclosed a printable ink comprising a small molecular organic material based on an aromatic ketone or aromatic ether solvent (US20120205637); SEIKO EPSON CORPORATION disclosed a printable ink comprising an organic polymer material based on a substituted benzene derivative solvent. Other examples relating to organic functional material printing inks include: CN102408776A, CN103173060A, CN103824959A, CN1180049C, CN102124588B, US2009130296A1 and US2014097406A1, etc.

Another type of functional materials suitable for printing is inorganic nanomaterial, particularly quantum dots. Quantum dots are a nano-sized semiconductor material having the quantum confinement effect. Quantum dots can emit fluorescent light of specific energy when stimulated by light or electricity, and color (energy) of such fluorescent light is determined by the chemical compositions, particle size and shape of the quantum dots. Therefore, regulation of the particle size and shape of the quantum dots can effectively control the electronic and optical properties of the quantum dots. At present, many countries are conducting research in applications of quantum dots for full-color emission, mainly in the display field. In recent years, electroluminescent devices including quantum dots as a light emitting layer (QLED) have been developed rapidly and lifetime of such devices is prolonged greatly, as reported by Peng et al., Nature Vol51596 (2015) and Qian et al., Nature Photonics Vol9259 (2015). Up to now, pluralities of companies have reported quantum dot inks for printing: Nanoco Technologies Ltd. in the United Kingdom disclosed a method of a printable ink formulation containing nanoparticles (CN101878535B). A printable nanoparticle ink and a corresponding film containing nanoparticles are obtained by selecting a suitable solvent such as toluene and dodecaneselenol. Samsung Electronics disclosed a quantum dot ink for ink-jet printing (U.S. Pat. No. 8,765,014B2). The ink contains a certain concentration of quantum dots, an organic solvent and a polyalcohol additive. A quantum dot film is printed from the ink to manufacture a quantum dot electroluminescent device. QD Vision Inc. disclosed a quantum dot ink formulation, comprising a host material, a quantum dot material and an additive (US2010264371A1).

Other patent literature relating to quantum dot printing inks includes US2008277626A1, US2015079720A1, US2015075397A1, TW201340370A, US2007225402A1, US2008169753A1, US2010265307A1, US2015101665A1 and WO2008105792A2. However, in these disclosed patent documents, all quantum dot inks include other additives such as alcohol polymer for regulating physical parameters of the inks. Introduction of the insulating polymer additives tends to reduce charge transporting abilities of films, negatively affects optoelectronic properties of devices, and thus limits applications of quantum dot inks in optoelectronic devices.

### SUMMARY

One of the objects of the present disclosure is to provide a new formulation for printing electronic device.

A technical solution of the present disclosure is as follows:

A formulation for printing electronic device comprises at least one functional material and a solvent system containing at least one organic solvent based on alicyclic structure and having general formula (I):

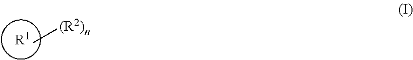

wherein, R¹ is an alicyclic or heteroalicylic structure having 3 to 20 ring atoms; n is an integer greater than or equal to 0, and R² is a substituent when n≥1. The boiling point of the organic solvent is equal to or larger than 150° C., and the organic solvent can be evaporated from the solvent system to form a functional material film.

In one embodiment of the above-described formulation for printing electronic device, the organic solvent based on alicyclic structure and having general formula (I) has a viscosity from 1 cPs to 100 cPs at 25° C.

In one embodiment of the above-described formulation for printing electronic device, the organic solvent based on alicyclic structure and having general formula (I) has a surface tension from 19 dyne/cm to 50 dyne/cm at 25° C.

In one embodiment of the above-described formulation for printing electronic device, R¹ in the organic solvent based on alicyclic structure and having general formula (I) has any one structure selected from general formulas shown below:

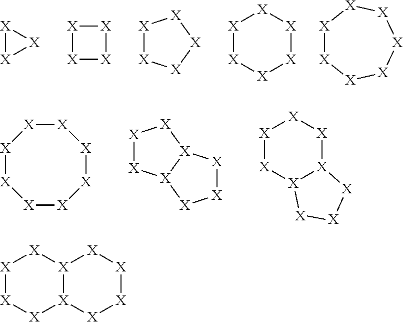

wherein, X is selected from CR³R⁴, C(═O), S, S(═O)₂, O, SiR⁵R⁶, NR⁷, or P(═O)R⁸, each R³, R⁴, R⁵, R⁶, R⁷, R⁸ can be independently selected from any one of the following: H, D, straight-chain alkyl, straight-chain alkoxy, or straight-chain thioalkoxy each containing 1 to 20 C atoms, branched or cyclic alkyl, branched or cyclic alkoxy, branched or cyclic thioalkoxy, or branched or cyclic silyl each containing 3 to 20 C atoms, substituted keto containing 1 to 20 C atoms, alkoxycarbonyl containing 2 to 20 C atoms, aryloxycarbonyl containing 7 to 20 C atoms, cyano (—CN), carbamoyl (—C(═O)NH₂), haloformyl (—C(═O)-X, wherein X represents a halogen atom), formyl (—C(═O)—H), isocyano, isocyanate, thiocyanate, isothiocyanate, hydroxyl, nitro, CF₃, Cl, Br, F, crosslinkable group, substituted or unsubstituted aromatic or heteroaromatic ring system containing 5 to 40 ring atoms, or aryloxy or heteroaryloxy containing 5 to 40 ring atoms; wherein when one or some of R³, R⁴, R⁵, R⁶, R⁷, R⁸ exist simultaneously, they can exist independently, or can form a monocyclic or polycyclic aliphatic or aromatic ring system with each other and/or with R¹ or R².

In one embodiment of the above-described formulation for printing electronic device, each R² can be identically or differently selected from any one of the following: straight-chain alkyl, straight-chain alkoxy or straight-chain thioalkoxy each containing 1 to 20 C atoms, branched or cyclic alkyl, branched or cyclic alkoxy, branched or cyclic thioalkoxy or silyl each containing 3 to 20 C atoms, substituted keto containing 1 to 20 C atoms, alkoxycarbonyl containing 2 to 20 C atoms; aryloxycarbonyl containing 7 to 20 C atoms, cyano (—CN), carbamoyl (—C(═O)NH₂), haloformyl (—C(═O)-X; wherein X represents a halogen atom), formyl (—C(═O)—H), isocyano, isocyanate, thiocyanate or isothiocyanate, hydroxyl, nitro, CF₃, Cl, Br, F, crosslinkable group, substituted or unsubstituted aromatic or heteroaromatic ring system containing 5 to 40 ring atoms, or aryloxy or heteroaryloxy containing 5 to 40 ring atoms; wherein when one or some of R² can exist simultaneously, they can exist independently or can form a monocyclic or polycyclic aliphatic or aromatic ring system with each other and/or with the groups.

In one embodiment of the above-described formulation for printing electronic device, the organic solvent based on alicyclic structure and having general formula (I) can be selected from: tetralin, cyclohexylbenzene, decahydronaphthalene, 2-phenoxytetrahydrofuran, 1,1′-bicyclohexyl, butyl cyclohexane, ethyl abietate, benzyl abietate, ethylene glycol carbonate, styrene oxide, isophorone, 3,3,5-trimethylcyclohexanone, cycloheptanone, fenchone, 1-tetralone, 2-tetralone, 2-(phenylepoxy)tetralone, 6-(methoxy)tetralone, γ-butyrolactone, γ-valerolactone, 6-hexanolactone, N,N-diethylcyclohexylamine, sulfolane, 2,4-dimethylsulfone, or from a mixture of any two or more thereof.

In one embodiment of the above-described formulation for printing electronic device, the solvent system is a mixture further comprising at least one other organic solvent, and the organic solvent based on alicyclic structure and having general formula (I) accounts for 50% or more of the total weight of the mixed solvent.

In one embodiment of the above-described formulation for printing electronic device, the functional material is inorganic nanomaterial.

In one embodiment of the above-described formulation for printing electronic device, the functional material is a quantum dot material, that is, its particle size has a monodisperse distribution, and its shape can be selected from different nano-morphologies such as spherical nano-morphology, cubic nano-morphology, rod-like nano-morphology, branched structure nano-morphology, etc.

In one embodiment of the above-described formulation for printing electronic device, the functional material is a luminescent quantum dot material, and its light emitting wavelength is between 380 nm and 2500 nm.

In one embodiment of the above-described formulation for printing electronic device comprises an inorganic functional material selected from binary or multinary semiconductor compounds from Group IV, Group II-VI, Group II-V, Group III-V, Group III-VI, Group IV-VI, Group I-III-VI, Group II-IV-VI, Group II-IV-V of the Periodic Table of the Elements, or from a mixture of any two or more thereof.

In one embodiment of the above-described formulation for printing electronic device, the functional material can be a perovskite nanoparticle material, in one embodiment, the functional material can be a luminescent perovskite nanomaterial, a metal nanoparticle material, a metal oxide nanoparticle material, or a mixture of any two or more thereof.

In one embodiment of the above-described formulation for printing electronic device, the functional material is an organic functional material.

In one embodiment of the above-described formulation for printing electronic device, the organic functional material can be selected from: a hole injection material (HIM), a hole transport material (HTM), an electron transport material (ETM), an electron injection material (EIM), an electron blocking material (EBM), a hole blocking material (HBM), an emitter, a host material (Host), an organic dye, or from a mixture of any two or more thereof.

In one embodiment of the above-described formulation for printing electronic device, the organic functional material can comprise at least one host material and at least one emitter.

In one embodiment of the above-described formulation for printing electronic device, the functional material can account for 0.3%˜30% of the total weight of the formulation, and contained organic solvent can account for 70%˜99.7% of the total weight of the formulation.

Another object of the present disclosure is to provide an electronic device comprising a functional layer printed from any of the above-described formulation for printing electronic device, and the organic solvent based on alicyclic structure and having general formula (I) contained in the formulation can be evaporated from the solvent system to form a functional material film.

In one embodiment, the above-described electronic device can be selected from a quantum dot light emitting diode (QLED), a quantum dot photovoltaic cell (QPV), a quantum dot light emitting electrochemical cell (QLEEC), a quantum dot field effect transistor (QFET), a quantum dot light emitting field effect transistor, a quantum dot laser, a quantum dot sensor, an organic light emitting diode (OLED), an organic photovoltaic cell (OPV), an organic light emitting electrochemical cell (OLEEC), an organic field effect transistor (OFET), an organic light emitting field effect transistor, an organic laser, an organic sensor, etc.

Another object of the present disclosure is to provide a method for preparing a functional material film comprising: disposing the above-described formulation for printing electronic device on a substrate by printing or coating methods, wherein the printing or coating methods can be selected from (but are not limited to): inkjet printing, nozzle printing, typographic printing, screen printing, dip coating, spin coating, blade coating, roller printing, torsion roller printing, lithographic printing, flexographic printing, rotary printing, spray coating, brush coating, pad printing, or slot die coating, etc.

Another object of the present disclosure further relates to a printing process of the formulation and an application of the formulation in an electronic device, in particular in an electroluminescent device.

Beneficial effects of the present disclosure include that viscosity and surface tension of the formulation for printing electronic device can be adjusted to an appropriate scope in use according to a specific printing process, particularly the inkjet printing, thus facilitating the printing process and forming a film with a uniform surface. Moreover, the organic solvent can be removed effectively by a post treatment process, such as a heat treatment or a vacuum treatment, and thus ensuring performance of the electronic device. Accordingly, the present disclosure provides the ink formulation, particularly the printing ink comprising the quantum dots and the organic semiconductor material, for preparing a high-quality functional film to provide an effective technical solution for printed electronic device or optoelectronic device.

### BRIEF DESCRIPTION OF THE DRAWINGS

FIG. 1 is a structural view of one embodiment of the present disclosure of a light emitting device, wherein 101 is a substrate; 102 is an anode; 103 is a hole injection layer (HIL) or a hole transport layer (HTL); 104 is a light emitting layer (an electroluminescent device) or a light absorbing layer (a photovoltaic cell); 105 is an electron injection layer (EIL) or an electron transport (ETL); 106 is a cathode.

### DETAILED DESCRIPTION

The present disclosure provides a new formulation for printing electronic device. The provided formulation comprises at least one functional material and at least one organic solvent based on alicyclic structure. In one embodiment, the organic solvent based on alicyclic structure has a viscosity from 1 cPs to 100 cPs at 25° C., has a surface tension from 19 dyne/cm to 50dyne/cm, and has a boiling point more than 150° C. at 25° C. The present disclosure also relates to a printing progress of the formulation and an application of the formulation in an electronic device, particularly in an electroluminescent device. The present disclosure further relates to an electronic device prepared from the formulation.

In order to make the purpose, the technical solution and the advantages of the present disclosure clearer and more definite, detailed descriptions of the present disclosure are described below. It should be understood that the detailed descriptions of the disclosure are used to explain the present disclosure only, instead of limiting the present disclosure.

One embodiment of the present disclosure provides a formulation for printing electronic device, the formulation comprising at least one functional material and a solvent system containing at least one organic solvent based on alicyclic structure and having general formula (I):

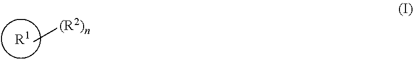

where R¹ is an alicyclic or heteroalicylic structure having 3 to 20 ring atoms, n is an integer greater than or equal to 0, and R² is a substituent when n≥1. The boiling point of the organic solvent is equal to or larger than 150° C., and the organic solvent can be evaporated from the solvent system to form a film containing the functional material.

Boiling point is a parameter that should be considered when choosing a solvent to dissolve the functional material. In some embodiments of the present disclosure, the organic solvent based on alicyclic structure and having general formula (I) has a boiling point equal to or above 150° C. In some embodiments, the organic solvent based on alicyclic structure and having general formula (I) has a boiling point equal to or above 180° C. or equal to or above 200° C.; in some embodiments, the organic solvent based on alicyclic structure and having general formula (I) has a boiling point equal to or above 220° C.; in other embodiments, the organic solvent based on alicyclic structure and having general formula (I) has a boiling point equal to or above 250° C. or equal to or above 350° C. The boiling points in these ranges are beneficial for preventing nozzle clogging of the inkjet print head. The organic solvent can be evaporated from the solvent system by vacuum drying or other ways to form a film containing the functional material.

In one embodiment of the present disclosure, the organic solvent based on alicyclic structure and having general formula (I) contained in the formulation has a viscosity from 1 cPs to 100 cPs at 25° C.

Viscosity is a parameter that should be considered when choosing a solvent to dissolve the functional material. The viscosity can be adjusted by different methods, such as by choosing a example of organic solvent or a concentration of the functional material in the ink. In one embodiment of the present disclosure, the organic solvent based on alicyclic structure and having general formula (I) has a viscosity from 1 cPs to 100 cPs at 25° C.; in another embodiment, from 1 cPs to 50 cPs; in yet another embodiment, from 1.5 cPs to 20 cPs.

The content of the organic solvent based on alicyclic structure of the present disclosure in the ink, can be conveniently adjusted in an appropriate range according to the applied printing method. Ordinarily, in the printing ink of the present disclosure, the functional material can account for 0.3%˜30% of the total weight of the formulation, in one embodiment account for 0.5%˜20% of the total weight of the formulation, in another embodiment, account for 0.5%˜15% of the total weight of the formulation, and in yet another embodiment, account for 1%˜10% of the total weight of the formulation. In one embodiment, the viscosity of the ink containing the organic solvent based on alicyclic structure is less than 100 cPs at the above composition ratio. In another embodiment, the viscosity of the ink containing the organic solvent based on alicyclic structure is less than 50 cPs at the above composition ratio. In another embodiment, the viscosity of the ink containing the organic solvent based on alicyclic structure ranges from 1.5 to 20 cPs at the above composition ratio. The viscosity here is referred to a viscosity at an ambient temperature during printing; ordinarily at a temperature between 15 and 30° C., in one embodiment, at a temperature between 18 and 28° C., in another embodiment, at a temperature between 20 and 25° C,in yet another embodiment, at a temperature between 23 and 25° C. The printing ink formulated in this way is particularly suitable for inkjet printing.

In one embodiment of the present disclosure, the organic solvent contained in the formulation based on alicyclic structure and having general formula (I) has a surface tension from 19 dyne/cm to 50 dyne/cm at 25° C.

A suitable surface tension parameter of the ink is suitable for a specific substrate and a particular printing method. For example, for inkjet printing, in one embodiment, the surface tension of the organic solvent based on alicyclic structure and having general formula (I) is from about 19 dyne/cm to 50 dyne/cm at 25° C.; in another embodiment, the surface tension of the organic solvent based on alicyclic structure and having general formula (I) is from 22 dyne/cm to 35 dyne/cm at 25° C.; in yet another embodiment, the surface tension of the organic solvent based on alicyclic structure and having general formula (I) is from 25 dyne/cm to 33 dyne/cm at 25° C.

In one embodiment, the surface tension of the ink of the present disclosure is from about 19 dyne/cm to 50 dyne/cm at 25° C.; in another embodiment, the surface tension of the ink of the present disclosure is from 22 dyne/cm to 35 dyne/cm at 25° C., in yet another embodiment, the surface tension of the ink of the present disclosure is from of 25 dyne/cm to 33 dyne/cm at 25° C.

By using the solvent system containing the organic solvent based on alicyclic structure and having general formula (I) having the above-mentioned boiling point, surface tension parameter, and viscosity parameter, the obtained ink can form a functional material film having a uniform thickness and uniform formulation property.

In one embodiment of the above-described formulation for printing electronic device, R¹ in the organic solvent based on alicyclic structure and having general formula (I) has a structure selected from any one of general formulas shown below:

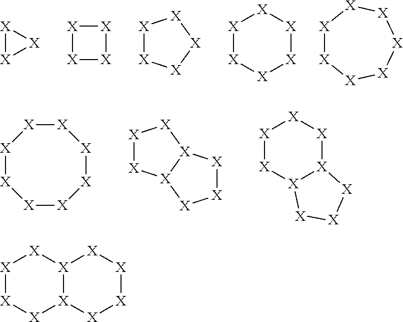

wherein X is selected from CR³R⁴, C(═O), S, S(═O)₂, O, SiR⁵R⁶, NR⁷, or P(═O)R⁸,

each R³, R⁴, R⁵, R⁶, R⁷, R⁸ can be independently selected from any one of the following: H, D, straight-chain alkyl, straight-chain alkoxy, or straight-chain thioalkoxy each containing 1 to 20 C atoms, branched or cyclic alkyl, branched or cyclic alkoxy, branched or cyclic thioalkoxy, or branched or cyclic silyl each containing 3 to 20 C atoms, substituted keto containing 1 to 20 C atoms, alkoxycarbonyl containing 2 to 20 C atoms, aryloxycarbonyl containing 7 to 20 C atoms, cyano (—CN), carbamoyl (—C(═O)NH₂), haloformyl (—C(═O)-X, wherein X represents a halogen atom), formyl (—C(═O)—H), isocyano, isocyanate, thiocyanate, isothiocyanate, hydroxyl, nitro, CF₃, Cl, Br, F, crosslinkable group, substituted or unsubstituted aromatic or heteroaromatic ring system containing 5 to 40 ring atoms, or aryloxy or heteroaryloxy containing 5 to 40 ring atoms; wherein when one or some of R³, R⁴, R⁵, R⁶, R⁷, R⁸ exist simultaneously, they can exist independently, or can form a monocyclic or polycyclic aliphatic or aromatic ring system with each other and/or with R¹ or R².

In some embodiments, each R³, R⁴, R⁵, R⁶, R⁷, R⁸ can be identically or differently selected from any one of the following: H, D, straight-chain alkyl, straight-chain alkoxy, or straight-chain thioalkoxy each containing 1 to 10 C atoms, branched or cyclic alkyl, branched or cyclic alkoxy, branched or cyclic thioalkoxy, or branched or cyclic silyl each containing 3 to 10 C atoms, substituted keto containing 1 to 10 C atoms, alkoxycarbonyl containing 2 to 10 C atoms, aryloxycarbonyl containing 7 to 10 C atoms, cyano (—CN), carbamoyl (—C(═O)NH₂), haloformyl (—C(═O)-X, wherein X represents a halogen atom), formyl (—C(═O)—H), isocyano, isocyanate, thiocyanate, isothiocyanate, hydroxyl, nitro, CF₃, Cl, Br, F, crosslinkable group, substituted or unsubstituted aromatic or heteroaromatic ring system containing 5 to 20 ring atoms, or aryloxy or heteroaryloxy containing 5 to 20 ring atoms; wherein when one or some of R³, R⁴, R⁵, R⁶, R⁷, R⁸ exist simultaneously, they can exist independently, or can form a monocyclic or polycyclic aliphatic or aromatic ring system with each other and/or with R¹ or R².

In another embodiment of the formulation for printing electronic device in the present disclosure, each R² contained in the organic solvent based on alicyclic structure and having general formula (I) can be identically or differently selected from any one of the following: straight-chain alkyl, straight-chain alkoxy or straight-chain thioalkoxy each containing 1 to 20 C atoms, branched or cyclic alkyl, branched or cyclic alkoxy, branched or cyclic thioalkoxy or silyl each containing 3 to 20 C atoms,substituted keto containing 1 to 20 C atoms, alkoxycarbonyl containing 2 to 20 C atoms, aryloxycarbonyl containing 7 to 20 C atoms, cyano (—CN), carbamoyl (—C(═O)NH₂), haloformyl (—C(═O)-X; wherein X represents a halogen atom), formyl (—C(═O)—H), isocyano, isocyanate, thiocyanate or isothiocyanate, hydroxyl, nitro, CF₃, Cl, Br, F, crosslinkable groups or optionally substituted or unsubstituted aromatic or heteroaromatic ring system containing 5 to 40 ring atoms, or aryloxy or heteroaryloxy containing 5 to 40 ring atoms; wherein when one or some of R² can exist simultaneously, they can exist independently or can form a monocyclic or polycyclic aliphatic or aromatic ring system with each other and/or with the groups.

In another embodiment, each R² can be identically or differently selected from any one of the following: straight-chain alkyl, straight-chain alkoxy or straight-chain thioalkoxy each containing 1 to 10 C atoms, branched or cyclic alkyl, branched or cyclic alkoxy, branched or cyclic thioalkoxy or silyl each containing 3 to 10 C atoms, substituted keto containing 1 to 10 C atoms, alkoxycarbonyl containing 2 to 10 C atoms, aryloxycarbonyl containing 7 to 10 C atoms, cyano (—CN), carbamoyl (—C(═O)NH₂), haloformyl (—C(═O)-X; wherein X represents a halogen atom), formyl (—C(═O)—H), isocyano, isocyanate, thiocyanate or isothiocyanate, hydroxyl, nitro, CF₃, Cl, Br, F, crosslinkable groups or optionally substituted or unsubstituted aromatic or heteroaromatic ring system containing 5 to 20 ring atoms, or aryloxy or heteroaryloxy containing 5 to 20 ring atoms; wherein when one or some of R² can exist simultaneously, they can exist independently or can form a monocyclic or polycyclic aliphatic or aromatic ring system with each other and/or with the groups.

In the formulation for printing electronic device described in the present disclosure, examples of the organic solvent based on alicyclic structure and having general formula (I) are but not limited to: tetralin, cyclohexylbenzene, decahydronaphthalene, 2-phenoxytetrahydrofuran, 1,1′-bicyclohexyl, butyl cyclohexane, ethyl abietate, benzyl abietate, ethylene glycol carbonate, styrene oxide, isophorone, 3,3,5-trimethylcyclohexanone, cycloheptanone, fenchone, 1-tetralone, 2-tetralone, 2-(phenylepoxy)tetralone, 6-(methoxy)tetralone, γ-butyrolactone, γ-valerolactone, 6-hexanolactone, N,N-diethylcyclohexylamine, sulfolane, 2,4-dimethylsulfone, or from a mixture of any two or more thereof.

In some other embodiments, the formulation of the present disclosure comprises at least two kinds of organic solvents, and the mixed solvent comprises at least one organic solvent based on alicyclic structure and having general formula (I) and at least one other organic solvent.

In one embodiment, the organic solvent based on alicyclic structure and having general formula (I) accounts for 50% or more of the total weight of the mixed solvent; in one embodiment, the organic solvent based on alicyclic structure and having general formula (I) accounts for 70% or more of the total weight of the mixed solvent; in one embodiment, the organic solvent based on alicyclic structure and having general formula (I) accounts for 80% or more of the total weight of the mixed solvent; in another embodiment, the organic solvent based on alicyclic structure and having general formula (I) accounts for 90% or more of the total weight of the mixed solvent; or the mixed solvent essentially consists of the organic solvent based on alicyclic structure and having general formula (I); or the mixed solvent totally consists of the organic solvent based on alicyclic structure and having general formula (I).

In one embodiment, the organic solvent based on alicyclic structure and having general formula (I) is cyclohexylbenzene.

In another embodiment, the solvent is a mixture of cyclohexylbenzene and at least one other solvent, and the cyclohexylbenzene accounts for 50% or more of the total weight of the mixed solvent; in one embodiment accounts for 80% or more of the total weight of the mixed solvent, in another embodiment accounts for 90% or more of the total weight of the mixed solvent.

In some embodiments, the organic solvent based on alicyclic structure and having general formula (I) is 1,1′-bicyclohexyl.

In one embodiment, the mixed solvent is a mixture of 1,1′-bicyclohexyl and at least one other solvent, and the 1,1′-bicyclohexyl accounts for more than 50% of the total weight of the mixed solvent, in another embodiment accounts for more than 80% of the total weight of the mixed solvent; in yet another embodiment, accounts for more than 90% of the total weight of the mixed solvent.

In some embodiments, the organic solvent based on alicyclic structure and having general formula (I) is γ-valerolactone.

In one embodiment, the solvent is a mixture of γ-valerolactone and at least one other solvent, and the γ-valerolactonel accounts for more than 50% of the total weight of the mixed solvent, in another embodiment accounts for more than 80% of the total weight of the mixed solvent, in yet another embodiment accounts for more than 90% of the total weight of the mixed solvent.

In some embodiments, the organic solvent based on alicyclic structure and having general formula (I) is sulfolane.

In one embodiment, the solvent is a mixture of sulfolane and at least one other solvent, and the sulfolane accounts for more than 50% of the total weight of the mixed solvent, in another embodiment, accounts for more than 80% of the total weight of the mixed solvent, in yet another embodiment accounts for more than 90% of the total weight of the mixed solvent.

Examples for the at least one other solvent described above include, but are not limited to: methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3 -phenoxytoluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decahydronaphthalene, indene, or a mixture of any two or more thereof.

The organic solvent based on alicyclic structure and having general formula (I) can effectively disperse functional materials, that is, as a new dispersant to replace the conventionally used dispersant for dispersing functional materials such as toluene, xylene, chloroform, chlorine benzene, dichlorobenzene, n-heptane, etc.

The boiling point, surface tension, and viscosity parameters of the above examples are listed below:

| | | Boiling | Surface tension | Viscosity |
|---|---|---|---|---|
| | | point | @RT | @RT |
| Name | Structural formula | (° C.) | (dyne/cm) | (cPs) |
| tetralin | 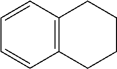 | 207 | 35.9 | 2 |
| cyclohexylbenzene | 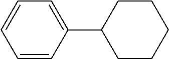 [SMILES: c1ccc(C2CCCCC2)cc1] | 238 | 34 | 4 |
| decahydronaphthalene | 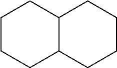 | 196 | 29 | 3.4 |
| 1,1′-Bicyclohexyl | 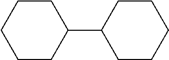 [SMILES: C1CCC(C2CCCCC2)CC1] | 239 | 33 | 3.75 |
| butyl cyclohexane | 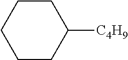 | 181 | 27 | 1.2 |
| butyrolactone | 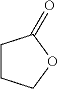 | 204 | 35 | 1.7 |
| ethylene glycol carbonate | 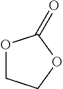 | 238 | 37 | 2 |
| styrene oxide | 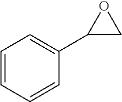 | 194 | 43 | 2 |
| isophorone | 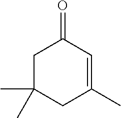 | 215 | 32 | 2.6 |
| cycloheptanone | 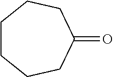 | 181 | 31.5 | 2.6 |
| fenchone | 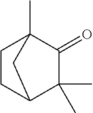 | 193 | 31 | 3.6 |
| 1-tetralone | 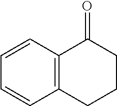 [SMILES: O=C1CCCc2ccccc21] | 256 | 42 | 8.6 |
| γ-butyrolactone | 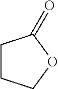 | 204 | 35 | 1.8 |
| γ-valerolactone | 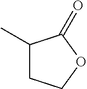 | 207 | 29 | 3.4 |
| 6-hexanolactone | 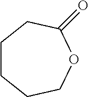 | 215 | 32 | 1.1 |
| sulfolane | 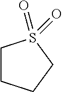 | 287 | 35 | 10 |
| 2,4-dimethylsulfone | 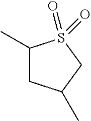 | 280 | 28 | 7.9 |

The printing ink can also further comprises one or more components such as a surfactant, a lubricant, a wetting agent, a dispersant, a hydrophobizing agent, a binder, etc, to adjust the viscosity and film forming property, and improving adhesion, etc.

A functional material film can be formed by depositing the printing ink by various printing or coating techniques. The printing or coating techniques can be selected from (but not limited to): inkjet printing, nozzle printing, typographic printing, screen printing, dip coating, spin coating, blade coating, roller printing, torsion roller printing, lithographic printing, flexographic printing, rotary printing, spraying, brushing coating, pad printing, or slot die coating. Embodiments of printing technologies are inkjet printing, screen printing, and typographic printing. The detailed information relevant to the printing technology and requirements on solution, such as solvent, concentration, and viscosity, can be referred to Handbook of Print Media: Technologies and Production Methods, Helmut Kipphan, ISBN 3-540-67326-1. In general, different printing technologies have different characteristics requirements for the inks used. For example, a printing ink suitable for inkjet printing needs to regulate the surface tension, viscosity, and wettability of the ink, so that the ink can be smoothly jetted through the nozzle under the printing temperature (e.g., room temperature, 25° C.) without being dried on the nozzle or clogging the nozzle, or it can form a continuous, flat and defect-free film on a specific substrate.

The formulation for printing electronic device described in the present disclosure comprises at least one functional material.

In the present disclosure, an embodiment of the functional material is a material having a photoelectric function. The photoelectric functions include, but not limited to: a hole injection function, a hole transport function, an electron transport function, an electron injection function, an electron blocking function, a hole blocking function, a light emitting function, a host function. Corresponding functional materials are hole injection material (HIM), hole transport material (HTM), electron transport material (ETM), electron injection material (EIM), electron blocking material (EBM), hole blocking material (HBM), emitter, host material (Host), organic dyes, or a mixture of two or more thereof.

The functional material can be organic material or inorganic material.

In one embodiment, at least one functional material contained in the formulation for printing electronic device described in the present disclosure is the inorganic nanomaterial.

In one embodiment, the inorganic nanomaterial is an inorganic semiconductor nanopaticle material.

In the present disclosure, the inorganic nanomaterial has an average particle size from about 1 nm to about 1000 nm. In some embodiments, the inorganic nanomaterial has an average particle size from about 1 nm to about 100 nm. In some embodiments, the inorganic nanomaterial has an average particle size from about 1 nm to about 20 nm, and in other embodiments, from 1 to 10 nm.

The inorganic nanomaterial can have different shapes, including but not limited to different nano-morphologies such as spherical nano-morphology, cubic nano-morphology, rod-like nano-morphology, disk-like nano-morphology, branched structure nano-morphology, etcand mixtures of particles with various shapes.

In one embodiment, the inorganic nanomaterial is quantum dot material with a very narrow monodisperse size distribution, i.e., the size difference among the particles is very small. In one embodiment, a root-mean-square deviation of size of the monodispersed quantum dot is smaller than 15% rms. In another embodiment, the root-mean-square deviation of size of the monodispersed quantum dot is smaller than 10% rms. In yet another embodimet, the root-mean-square deviation of size of the monodispersed quantum dot is smaller than 5% rms.

In another embodiment, the inorganic nanomaterial is a luminescent material. In yet another embodiment, the luminescent inorganic nanomaterial is a luminescent quantum dot material.

In general, a light emitting quantum dot can emit light in a wavelength ranged from 380 nm to 2500 nm. For example, it is found that a wavelength of light emitted from a quantum dot having a CdS core is in a range from about 400 nm to about 560 nm, a wavelength of light emitted from a quantum dot having a CdSe core is in a range from about 490 nm to about 620 nm, a wavelength of light emitted from a quantum dot having a CdTe core is in a range from about 620 nm to about 680 nm, a wavelength of light emitted from a quantum dot having a InGaP core is in a range from about 600 nm to about 700 nm, a wavelength of light emitted from a quantum dot having a PbS core is in a range from about 800 nm to about 2500 nm, a wavelength of light emitted from a quantum dot having a PbSe core is in a range from about 1200 nm to about 2500 nm, a wavelength of light emitted from a quantum dot having a CuInGaS core is in a range from about 600 nm to about 680 nm, a wavelength of light emitted from a quantum dot having a ZnCuInGaS core is in a range from about 500 nm to about 620 nm, and a wavelength of light emitted from a quantum dot having a CuInGaSe core is in a range from about 700 nm to about 1000 nm.

In one embodiment, the quantum dot material includes at least one material that can emit blue light having an emission peak wavelength ranged from 450 nm to 460 nm, or green light having an emission peak wavelength ranged from 520 nm to 540 nm, or red light having an emission peak wavelength ranged from 615 nm to 630 nm, or a mixture of any two or more thereof.

The quantum dot contained in the above material can be selected from the quantum dot having special chemical constitution, morphology structure, and/or size to obtain a light with a required wavelength emitted under an electrical stimulation.

The narrow size distribution of the quantum dot can make the quantum dot to have narrower luminescent spectrum. In addition, in applications, the size of the quantum dot needs to be adjusted within the above size ranges according to different chemical compositions and structures to obtain the luminescent property having the required wavelength.

In one embodiment, the luminescent quantum dot is a semiconductor nanocrystal. In one embodiment, a size of the semiconductor nanocrystal is in a range from about 2 nm to about 15 nm. In addition, the size of the quantum dot needs to be adjusted in the above size ranges according to different chemical compositons and structures to obtain the luminescent property having the required wavelength.

The semiconductor nanocrystal includes at least one semiconductor material, wherein the semiconductor material can be selected from a binary semiconductor compound or a multinary semiconductor compound of Group IV, Group II-VI, Group II-V, Group III-V, Group III-VI, Group IV-VI, Group I-III-VI, Group II-IV-VI, Group II-IV-V of the Periodic Table of the Elements, or mixtures thereof. The specific examples of the semiconductor material include, but are not limited to, Group IV semiconductor compounds, which are, for example, elemental Si, elemental Ge, binary compound SiC, and binary compound SiGe; Group II-VI semiconductor compounds, which are, for example, binary compounds including CdSe, CdTe, CdO, CdS, CdSe, ZnS, ZnSe, ZnTe, ZnO, HgO, HgS, HgSe, HgTe, trinary compounds including CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS, HgSeSe, and quaternary compounds including CgHgSeS, CdHgSeTe, CgHgSTe, CdZnSeS, CdZnSeTe, HgZnSeTe, HgZnSTe, CdZnSTe, HgZnSeS; Group III-V semiconductor compounds, which are, for example, binary compounds including AN, AlP, AlAs, AlSb, GaN, GaP, GaAs, GaSb, InN, InP, InAs, InSb, trinary compounds including AlNP, AlNAs, AlNSb. AlPAs, AlPSb, GaNP, GaNAs, GaNSb, GaPAs, GaPSb, InNP, InNAs, InNSb, InPAs, InPSb, and quaternary compounds including GaAlNAs, GaAlNSb, GaAlPAs, GaInNP, GaInNAs, GaInNSb, GaInPAs, GaInPSb, InAlNP, InAlNAs, InAiNSb, InAlPAs, InAlPSb; Group IV-VI semiconductor compounds , which are, for example, binary compounds including SnS, SnSe, SnTe, PbSe, PbS, PbTe, trinary compounds including SnSeS, SnSeTe, SnSTe, SnPbS, SnPbSe, SnPbTe, PbSTe, PbSeS, PbSeTe, and quaternary compounds including SnPbSSe, SnPbSeTe, SnPbSTe.

In one embodiment, the luminescent quantum dot includes Group II-VI semiconductor material which can be selected from CdSe, CdS, CdTe, ZnO, ZnSe, ZnS, ZnTe, HgS, HgSe, HgTe, CdZnSe and any combination thereof. In one embodiment, CdSe and CdS can be used as the luminescent quantum dot of visible light due to their synthesis processes are developed relatively well.

In another embodiment, the luminescent quantum dot includes Group III-V semiconductor material which can be selected from InAs, InP, InN, GaN, InSb, InAsP, InGaAs, GaAs, GaP, GaSb, AlP, AlN, AlAs, AlSb, CdSeTe, ZnCdSe, and a mixture of any two or more thereof.

In another embodiment, the luminescent quantum dot includes Group IV-VI semiconductor material which can be selected from PbSe, PbTe, PbS, PbSnTe, Tl₂SnTe₅, and a mixture of any two or more thereof.

In one embodiment, the quantum dot has a core-shell structure. The core and the shell respectively identically or differently include one or more kinds of semiconductor materials.

The core of the quantum dot can be selected from the above binary semiconductors compound or multinary semiconductor compounds of Group IV, Group II-VI, Group II-V, Group III-V, Group III-VI, Group IV-VI, Group I-III-VI, Group II-IV-VI, Group II-IV-V of the Periodic Table of the Elements. The special examples used to the core of the quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, and alloy or mixture of any two or more thereof.

The shell of the quantum dot includes a semiconductor material identical to or different from that of the core of quantum dot. The semiconductor material of the shell includes the binary semiconductor compound or the multinary semiconductor compound of Group IV, Group II-VI, Group II-V, Group III-V, Group III-VI, Group IV-VI, Group I-III-VI, Group II-IV-VI, or Group II-IV-V of the Periodic Table of the Elements. The specific examples of the shell of the quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, Pb Se, PbTe, Ge, Si, and alloy or mixture of any two or more thereof.

In the quantum dot having the core-shell structure, the shell can be a monolayer structure or a multilayer structure. The shell can include one or more semiconductor materials which are the same with or different from the material of the core. In one embodiment, the shell has a thickness of about 1 layer to about 20 layers. In yet another embodiment, the shell has a thickness of about 5 layers to about 10 layers. In some embodiments, two or more shells are grown on a surface of the core of the quantum dot.

In one embodiment, the semiconductor material of the shell can have a larger band gap than the core. in another embodiment, the shell and the core have type I semiconductor heterojunction structure.

In another embodiment, the semiconductor material of the shell can have a smaller band gap than the core.

In one embodiment, the semiconductor material of the shell can have an atomic crystal structure same with or similar to that of the core. This selection is beneficial to decrease a stress between the shell and the core to make the quantum dot more stable.

Examples of the luminescent quantum dot using the core-shell structure include, but are not limited to:

red light: CdSe/CdS, CdSe/CdS/ZnS, CdSe/CdZnS, and etc.;

green light: CdZnSe/CdZnS, CdSe/ZnS, and etc.;

blue light: CdS/CdZnS, CdZnS/ZnS, and etc.

A method for preparing the quantum dot is a colloidal growth method. In one embodiment, a making for preparing the monodispersed quantum dot is selected from hot-injection method and/or heating up method. The methods refer to documents Nano Res, 2009, 2, 425-447 and Chem. Mater., 2015, 27 (7), 2246-2285.

In one embodiment, the surface of the quantum dot can have an organic ligand. The organic ligand can control the growth process of the quantum dot, regulate the morphology of the quantum dot, and decrease surface defects of the quantum dot, thereby increasing the emission efficiency and stability of the quantum dot. The organic ligand can be selected from but is not limited to pyridine, pyrimidine, furan, amine, alkyl phosphine, alkyl phosphine oxide, alkyl phosphonic acid or alkyl phosphinic acid, alky thiol, and etc. Specific examples of the organic ligand include, but are not limited to, tri-n-octyl phosphine, tri-n-octyl phosphine oxide, trihydroxypropyl phosphine, tributyl phosphine, tri(dodecyl) phosphine, dibutyl phosphite, tributyl phosphite, octadecyl phosphite, trilauryl phosphate, tridodecyl phosphite, triisodecyl phosphite, di(2-ethylhexyl) phosphate, tri(tridecyl) phosphate, hexadecylamine, oleylamine, octadecylamine, dioctadecylamine, trioctadecylamine, bis(2-ethylhexyl)amine, octylamine, dioctylamine, trioctylamine, dodecylamine, didodecylamine, tridodecylamine, hexadecylamine, phenyl phosphonic acid, hexyl phosphonic acid, tetradecyl phosphonic acid, octyl phosphonic acid, n-octadecyl phosphonic acid, propylene diphosphonic acid, dioctyl ether, diphenyl ether, octanethiol, dodecanethiol and etc, or a mixture of any two or more thereof.

In another embodiment, the surface of the quantum dot can have an inorganic ligand. The quantum dot protected by the inorganic ligand can be obtained through ligand exchange with the organic ligand on the surface of the quantum dot. The specific examples of the inorganic ligand include, but are not limited to, S²⁻, HS⁻, Se²⁻, HSe⁻, Te²⁻, HTe⁻, TeS₃²⁻, OH²⁻, NH₂²⁻, PO₄³⁻, MoO₄²⁻, or a mixture of any two or more thereof.

In some embodiments, the surface of the quantum dot can have one or more same or different ligands.

In one embodiment, the luminescence spectrum performed by the monodispersed quantum dots has a symmetrical peak shape and a narrow full width at half maxima (FWHM). In general, the better the monodispersity of the quantum dots, the more symmetrical the luminescence peak thereof, and the narrower the FWHM. In one embodiment, the FWHM of the luminescent spectrum of the quantum dot is smaller than 70 nm. In another embodiment, the FWHM of the luminescent spectrum of the quantum dot is smaller than 40 nm. In yet another embodiment, the FWHM of the luminescent spectrum of the quantum dot is smaller than 30 nm.

In general, a luminescence quantum efficiency of the quantum dot is larger than 10%, in one embodiment larger than 50%, in another embodinent larger than 60%, in yet another embodiment larger than 70%.

In another embodiment, the luminescent semiconductor nanocrystal is a nanorod. The properties of the nanorod are different from that of the spherical nanocrystal particle. For example, light emitted from the nanorod is polarized along a long axis of the nanorod, and light emitted from the spherical nanocrystal particle is not polarized. In addition, luminescence of the nanorod can be reversibly turned on and off under a control of an external electric field. Those properties of the nanorod can be incorporated into the device of the present disclosure in certain circumstances.

In other embodiments, in the formulation for printing electronic device described in the present disclosure, the inorganic nanomaterial is a perovskite nanoparticle material, particularly a luminescent perovskite nanoparticle material.

The perovskite nanoparticle material can have a general formula of AMX₃, wherein A can be selected from organic amine or alkali metal cation, M can be selected from metal cation, X can be selected from oxygen or halogen anions. Specific examples of the perovskite nanoparticle material include, but are not limited to, CsPbCl₃, CsPb(Cl/Br)₃, CsPbBr₃, CsPb(I/Br)₃, CsPbI₃, CH₃NH₃PbCl₃, CH₃NH₃Pb(Cl/Br)₃, CH₃NH₃PbBr₃, CH₃NH₃Pb(I/Br)₃, CH₃NH₃PbI₃, etc.

In another embodiment, in the formulation for printing electronic device described in the present disclosure, the inorganic nanomaterial can be a metal nanoparticle material, in one embodiment, a luminescent metal nanoparticle material. The metal nanoparticles can include, but are not limited to, nanoparticles of chromium (Cr), molybdenum (Mo), tungsten (W), ruthenium (Ru), rhodium (Rh), nickel (Ni), silver (Ag), copper (Cu) zinc (Zn), palladium (Pd), aurum (Au), osmium (Os), rhenium (Re), iridium (Ir), and platinum (Pt).

In another embodiment, the inorganic nanomaterial has a charge transport function.

In one embodiment, the inorganic nanomaterial has an electron transport capability. In one embodiment, such inorganic nanomaterials are selected from n-type semiconductor materials. Examples of the n-type inorganic semiconductor material can include, but are not limited to, metal chalcogenide, metal pnictide, or an elemental semiconductor such as metal oxide, metal sulfide, metal selenide, metal telluride, metal nitride, metal phosphide, or metal arsenide. Embodiments of the n-type inorganic semiconductor material can be selected from, but not limited to, ZnO, ZnS, ZnSe, TiO₂, ZnTe, GaN, GaP, AIN, CdSe, CdS, CdTe, CdZnSe, or mixtures of any two or more thereof.

In some embodiments, the inorganic nanomaterial has a hole transport capability. In one embodiment, such inorganic nanomaterials can be selected from p-type semiconductor materials. The inorganic p-type semiconductor nanomaterial can be selected from, but not limited to, NiOx, WOx, MoOx, RuOx, VOx, CuOx, or a mixture of any two or more thereof.

In some embodiments, the printing ink described in the present disclosure can include two or more kinds of the inorganic nanomaterials.

In another embodiment, the formulation for printing electronic device described in the present disclosure can include at least one kind of organic functional material.

The organic functional material can include, but is not limited to, a hole (also called electron hole) injection or transport material (HIM/HTM), a hole blocking material (HBM), an electron injection or transport material (EIM/ETM), an electron blocking material (EBM), an organic host material (Host), a singlet emitter (fluorescent emitter), a thermally activated delayed fluorescent material (TADF), a triplet emitter (phosphorescent emitter), especially a luminescent organic metal complex, an organic dyes, or mixtures of any two or more thereof.

In general, the solubility of a suitable organic functional material in the solvent based on alicyclic structure and having general formula (I) described in the present disclosure can be at least 0.2 wt %, in one embodiment at least 0.3 wt %, in another embodiment at least 0.6 wt %, in yet another embodiment at least 1.0 wt %, in yet another embodiment at least 1.5 wt %.

The organic functional material can be a small molecule or a polymer material. In the present disclosure, a small-molecule organic material refers to a material having a molecular weight of at most 4000 g/mol, and a material having a molecular weight of more than 4000 g/mol is collectively referred to as a polymer.

In one embodiment, the functional material contained in the formulation for printing electronic device described in the present disclosure can be a small molecule organic material.

In some embodiments, the organic functional material included in the formulation for printing electronic device described in the present disclosure can include at least one host material and at least one emitter.

In one embodiment, the organic functional material can include one kind of host material and one kind of singlet emitter.

In another embodiment, the organic functional material can include one kind of host material and one kind of triplet emitter.

In another embodiment, the organic functional material can include one kind of host material and one thermally activated delayed fluorescence material.

In other embodiments, the organic functional material can include one kind of hole transport material (HTM), in another embodiment the HTM can include crosslinkable groups.

Examples of small molecular organic functional materials of embodiments are described below in more details, but the present invention is not limited to these materials.

1. HIM/HTM/EBM

An example of organic HIM/HTM can optionally include but not limited to compounds having the following structure units: phthalocyanine, porphyrin, amine, aromatic amine, biphenyl triarylamine, thiophene, thiophthene, pyrrole, aniline, carbazole, indolocarbazole and derivatives thereof. In addition, an example of HIM also includes but is not limited to a polymer containing fluorocarbon, a polymer containing a conductive dopant, a conductive polymer, such as PEDOT:PSS.

An electron blocking layer (EBL) is used to block electrons from an adjacent functional layer, particularly a light-emitting layer. Compared to a light-emitting device without a blocking layer, the presence of EBL generally improves light emitting efficiency. The electron blocking material (EBM) of the electron blocking layer (EBL) needs to have a higher LUMO than an adjacent functional layer, such as a light emitting layer. In one embodiment, the HBM has a larger excited state energy level, such as a singlet state or a triplet state depending on the emitter, than the adjacent light-emitting layer. Moreover, the EBM has a hole transport function. Normally, the HIM/HTM materials, which have a high LUMO energy level, can be used as the EBM.

Embodiments of cyclic aromatic amine derivatives which can be applied as the HIM, HTM or EBM include (but are not limited to) the following general structure:

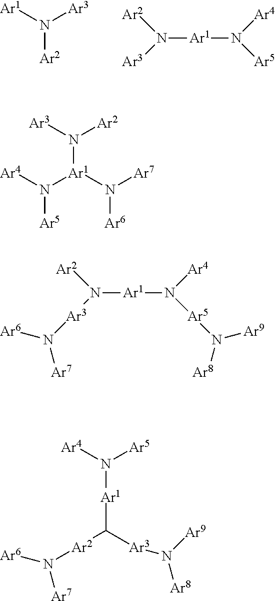

wherein, Ar¹ to Ar⁹ each can be selected independently from cyclic aromatic hydrocarbon compounds, such as benzene, biphenyl, triphenyl, benzo, naphthalene, anthracene, phenalene, phenanthrene, fluorene, pyrene, chrysene, perylene, azulene; from aromatic heterocyclic compounds, such as dibenzothiophene, dibenzofuran, furan, thiophene, benzofuran, benzothiophene, carbazole, pyrazole, imidazole, triazole, isoxazole, thiazole, oxadiazole, oxatriazole, dioxolane, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, naphthalene (cinnoline), quinazoline, quinoxaline, naphthalene, phthalein, pteridine, xanthene, acridine, phenazine, phenothiazine, phenoxazine, dibenzoselenophene, benzoselenophene, benzofuropyridine, indolocarbazole, pyridylindole, pyrrolodipyridine, furodipyridine, benzothienopyridine, thienodipyridine, benzoselenophenopyridine and selenophenodipyridine; or from groups containing 2 to 10 rings, which can be the same or different types of cyclic aromatic hydrocarbon groups or heterocyclic aromatic groups, and linked with each other directly or through at least one of the following groups: an oxygen atom, nitrogen atom, sulfur atom, silicon atom, phosphorus atom, boron atom, a chain structure unit, and an cyclic aliphatic group. Each Ar can be further substituted by a substituent. The substituent can be selected from but are not limited to hydrogen, alkyl, alkoxy, amino, alkenyl, alkynyl, aralkyl, heteroalkyl, aryl, and heteroaryl.

In one aspect, Ar¹ to Ar⁹ can comprises a group selected independently from but are not limited to the following groups:

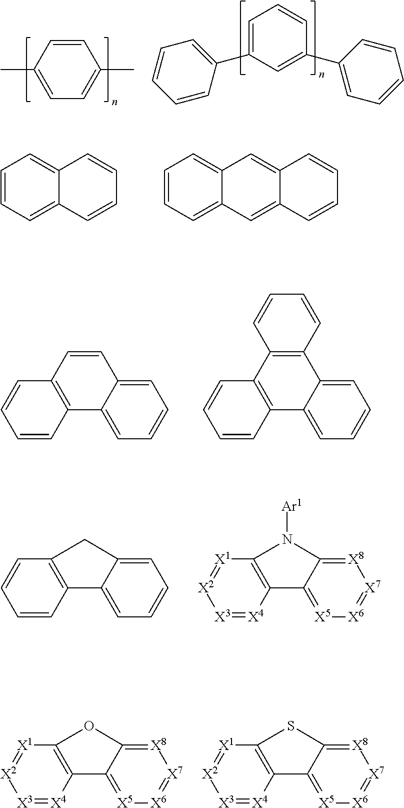

wherein, n is an integer from 1 to 20; X¹ to X⁸ is CH or N; Ar¹ is defined as above.

Embodiments of a metal complex that can be used as HTM or HIM include (but are not limited to) the following general structure:

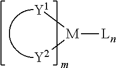

wherein M is a metal with an atomic weight greater than 40.

(Y¹-Y²) is a bidentate ligand. Y¹ and Y² can be independently selected from C, N, O, P and S; L is auxiliary ligand; m is an integer from 1 to a maximum coordination number of the metal; m+n is the maximum coordination number of the metal.

In one embodiment, (Y¹-Y²) is a 2-phenylpyridine derivative.

In another embodiment, (Y¹-Y²) is a carbene ligand.

In another embodiment, M can be selected from Ir, Pt, Os, and Zn.

In another aspect, HOMO of the metal complex is greater than −5.5 eV (with respect to vacuum energy level).

Examples of HIM/HTM compounds are listed as follows, but are not limited thereto:

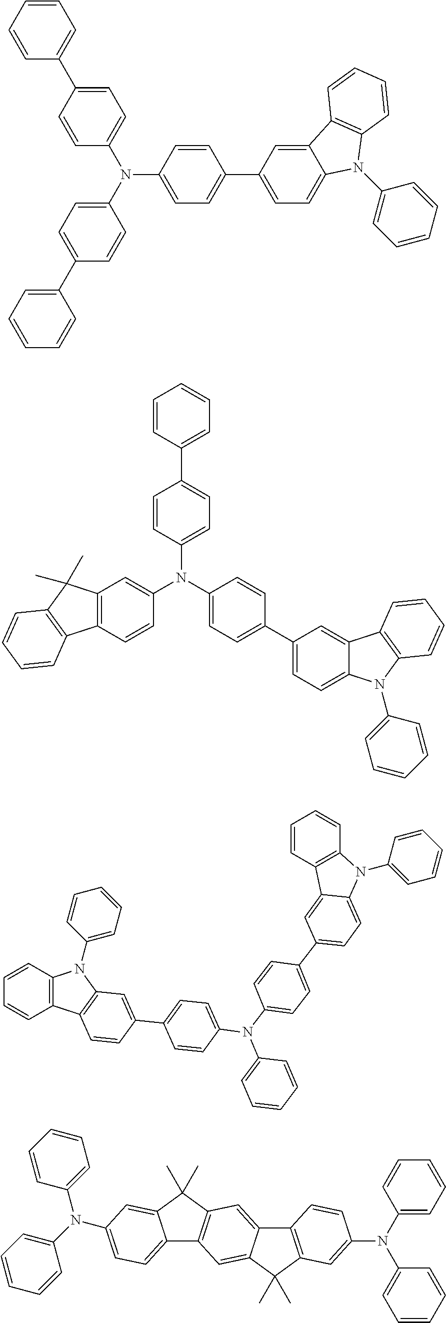 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc4c(c3)c3ccccc3n4-c3ccccc3)cc2)c2ccc(-c3ccc4c5ccccc5n(-c5ccccc5)c4c3)cc2)cc1 ; CC1(C)c2cc(N(c3ccccc3)c3ccccc3)ccc2-c2cc3c(cc21)-c1ccc(N(c2ccccc2)c2ccccc2)cc1C3(C)C]

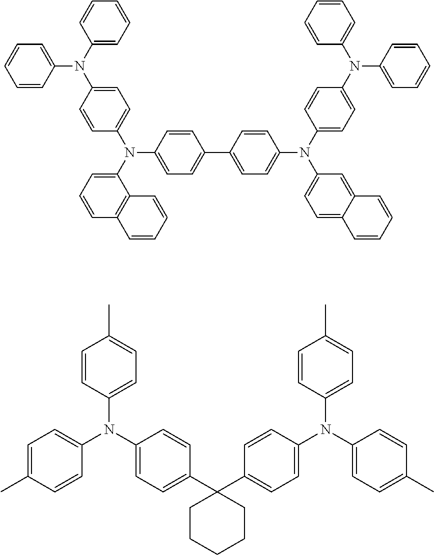

2. Triplet Host Material (Triplet Host)

There is no particular limitation of the triplet host material, and any metal complex or organic compound can be used as the host as long as the triplet energy thereof is higher than that of the emitter, particularly a triplet emitter or a phosphorescent emitter. Examples of metal complexes that can be used as a triplet host include, but are not limited to the following general structure:

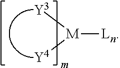

wherein M is a metal; (Y³-Y⁴) is a bidentate ligand; Y³ and Y⁴ can be independently selected from C, N, O, P, and S; L is auxiliary ligand; m is an integer from 1 to a maximum coordination number of the metal; and m+n is the maximum coordination number of the metal.

In one embodiment, the metal complex that can be used as a triplet host can have one of the following forms:

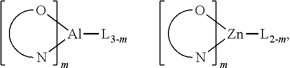

wherein (O—N) is a bidentate ligand, in which the metal is coordinated with O and N atoms.

In one embodiment, M can be selected from Ir and Pt.

Embodiments of the organic compounds which can be used as the triplet host can be selected from but are not limited to compounds comprising a cyclic aromatic hydrocarbon group, such as benzene, biphenyl, triphenyl, benzo, fluorine; from compounds comprising an aromatic heterocyclic group such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxolane, thiadiazole, pyridine, pyridazine, pyrimidine, pyrazine, triazine, oxazine, oxathiazine, oxadiazine, indole, benzimidazole, indazole, oxazole, dibenzoxazole, benzisoxazole, benzothiazole, quinoline, isoquinoline, phthalazine (cinnoline), quinazoline, quinoxaline, naphthalene, phthalide, pteridine, xanthene, acridine, phenazine, phenothiazine, phenoxazine, benzofuropyridine, furopyridine, benzothienopyridine, thienodipyridine, benzoselenophenopyridine and selenophene-benzodipyridine; from groups comprising 2 to 10 rings, which can be a same or different type of cyclic aromatic hydrocarbon groups or aromatic heterocyclic groups, and be linked with each other directly or through at least one of (but not limited to) the following groups: oxygen atom, nitrogen atom, sulfur atom, silicon atom, phosphorus atom, boron atom, a chain structure unit and an aliphatic ring group. Wherein, each Ar can be further substituted, and the substituent can be selected from but is not limited to hydrogen, alkyl, alkoxy, amino, alkenyl, alkynyl, aralkyl, heteroalkyl, aryl and heteroaryl.

In one embodiment, the triplet host material can be selected from compounds having at least one of the following groups, but not limited thereto:

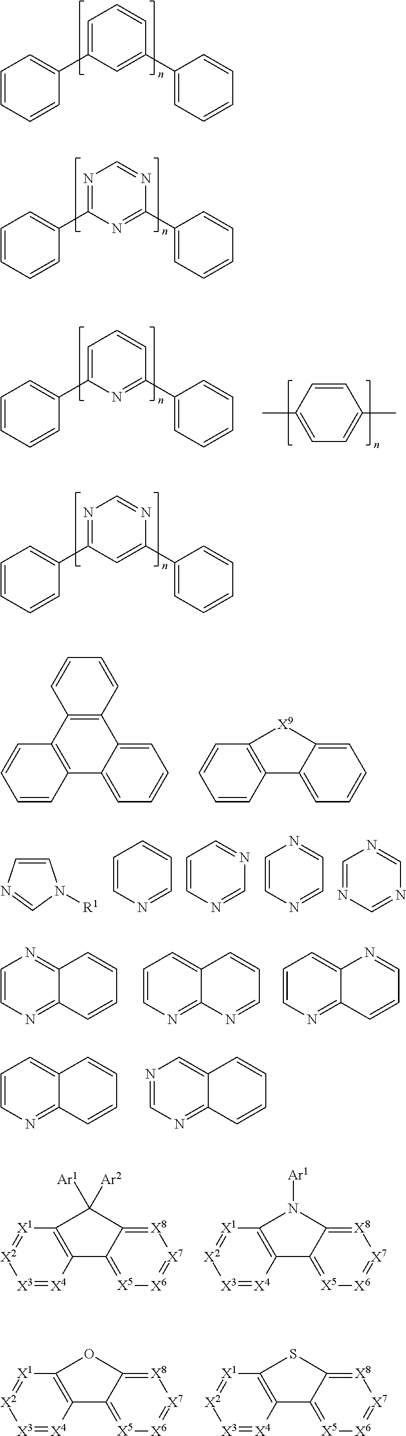

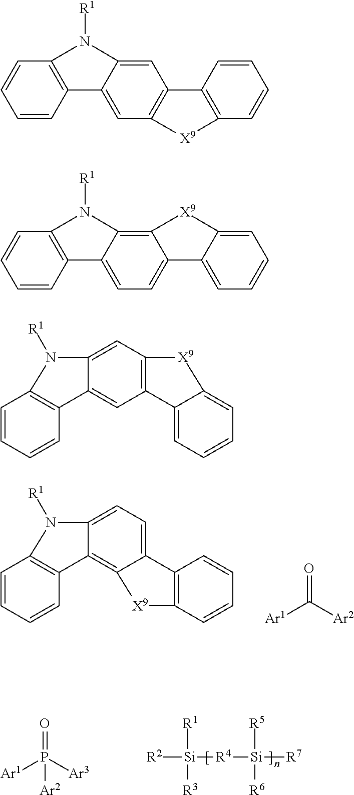

wherein R¹-R⁷ can be independently selected from but not limited to the following groups: hydrogen, alkyl, alkoxy, amino, alkenyl, alkynyl, aralkyl, heteroalkyl, aryl, and heteroaryl, and when R¹-R⁷ are aryl or heteroaryl, they have the same definitions as the above Ar¹ and Ar²; n is an integer from 0 to 20, each X¹-X⁸ is selected from CH or N; X⁹ is selected from CR¹R² or NR¹.

Examples of triplet host materials are listed as follows, but not limited to.

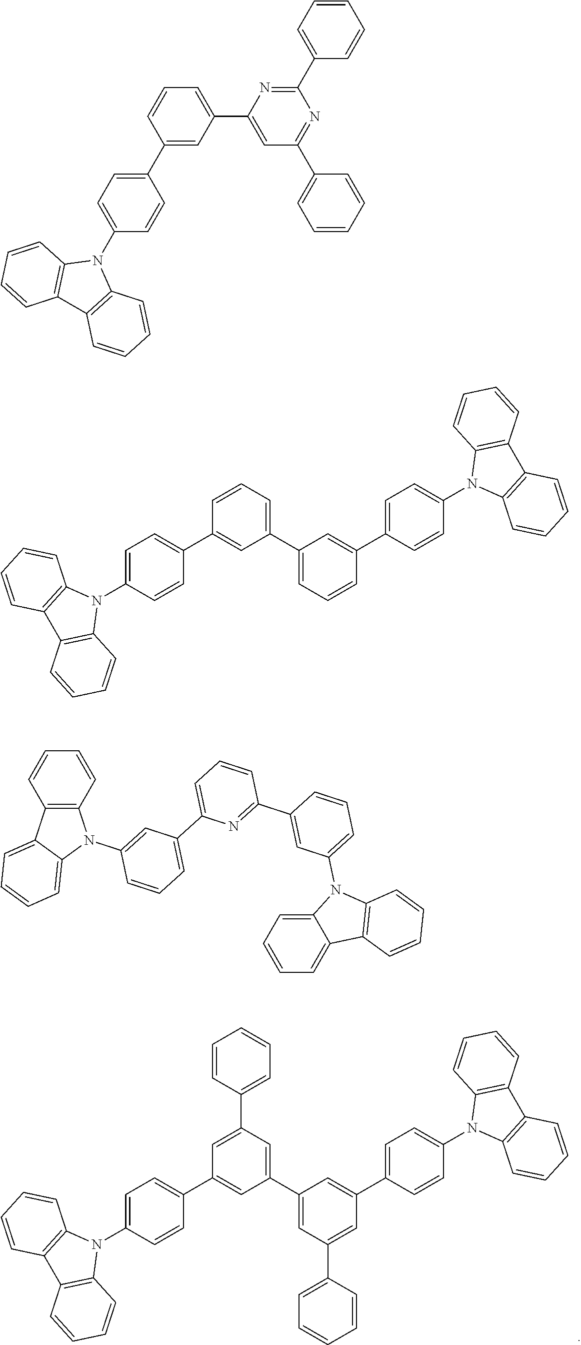 [SMILES: c1ccc(-c2cc(-c3cccc(-c4ccc(-n5c6ccccc6c6ccccc65)cc4)c3)nc(-c3ccccc3)n2)cc1 ; c1cc(-c2ccc(-n3c4ccccc4c4ccccc43)cc2)cc(-c2cccc(-c3ccc(-n4c5ccccc5c5ccccc54)cc3)c2)c1 ; c1cc(-c2cccc(-c3cccc(-n4c5ccccc5c5ccccc54)c3)n2)cc(-n2c3ccccc3c3ccccc32)c1 ; c1ccc(-c2cc(-c3ccc(-n4c5ccccc5c5ccccc54)cc3)cc(-c3cc(-c4ccccc4)cc(-c4ccc(-n5c6ccccc6c6ccccc65)cc4)c3)c2)cc1]

3. Singlet Host Material (Singlet Host)

There is no particular limitation of the singlet host material, and any organic compound can be used as the host as long as its singlet state energy is higher than that of the emitter, particularly a singlet emitter or a fluorescent emitter.

Examples of organic compounds that can be used as a singlet host material can be selected from, but are not limited to, cyclic aromatic hydrocarbon compounds, such as benzene, biphenyl, triphenyl, benzo, naphthalene, anthracene, phenalene, phenanthrene, fluorene, pyrene, chrysene, perylene, azulene; heteroaromatic compounds, such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, naphthalene (cinnoline), quinazoline, quinoxaline, naphthalene, phthalein, pteridine, xanthene, acridine, phenazine, phenothiazine, phenoxazine, benzofuropyridine, furodipyridine, benzothienopyridine, thienodipyridine, benzoselenophenopyridine and selenophenodipyridine; groups comprising 2 to 10 rings, which can be the same or different types of cyclic aromatic hydrocarbon groups or aromatic heterocyclic groups linked with each other directly or through at least one of the following groups: oxygen atom, nitrogen atom, sulfur atom, silicon atom, phosphorus atom, boron atom, a chain structure unit, and an aliphatic ring, but are not limited thereto.

In one embodiment, the singlet host material can be selected from, but are not limited to, compounds containing at least one of the following groups:

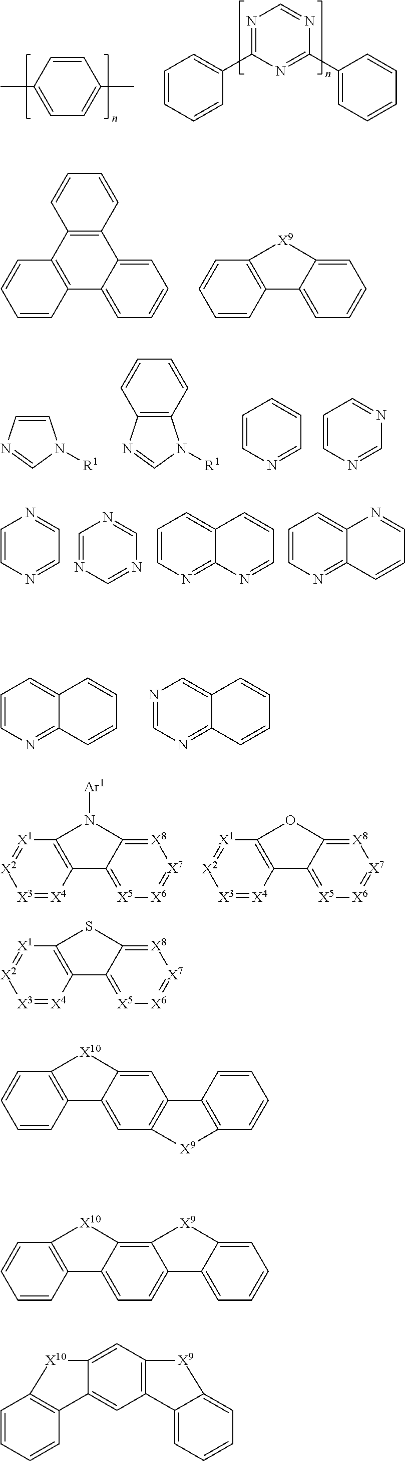

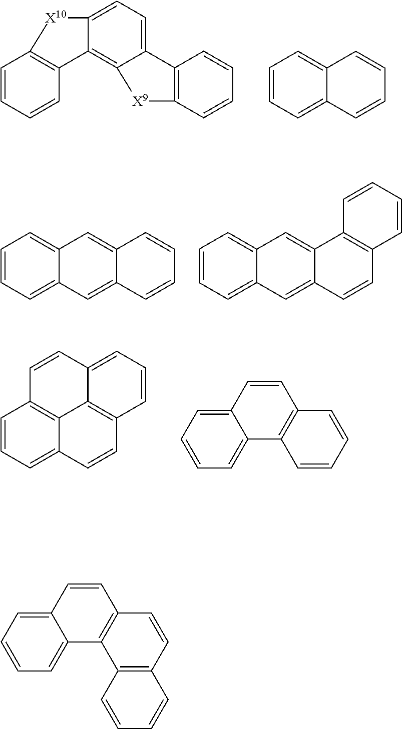

wherein R¹ can be independently selected from but not limited to the following groups: hydrogen, alkyl, alkoxy, amino, alkenyl, alkynyl, aralkyl, heteroalkyl, aryl and heteroaryl; Ar¹ is an aryl or heteroaryl, the definition thereof is the same as that of the Ar¹ and Ar² of the HTM; n is an integer from 0 to 20, X¹-X⁸ each is selected from CH or N; X⁹ and X¹⁰ are selected from CR¹R² or NR¹.

Some examples of anthryl singlet host materials are listed as follows but are not limited to:

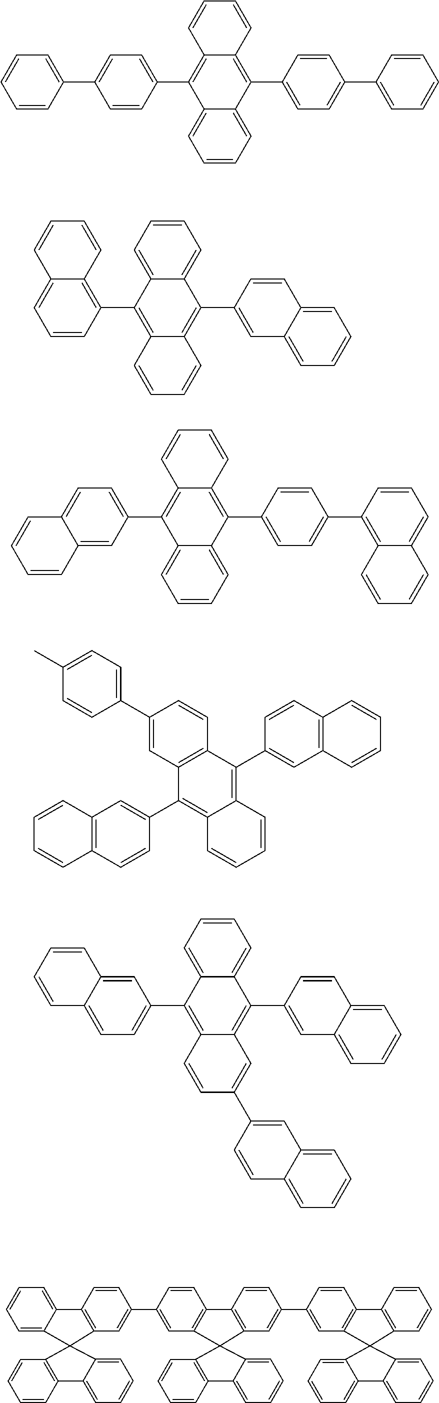

4. Singlet Emitter (Singlet Emitter)

Singlet emitter typically has a relatively long conjugated 7C electron system. So far, there have been many examples such as styrylamine and the derivatives thereof and indenofluorene and the derivatives thereof.

In one embodiment, the singlet emitter can be selected from but not limited to monostyrylamines, distyrylamines, tristyrylamines, tetrastyrylamines, styryl phosphines, styrylethers and arylamines.

The monostyrylamine refers to a compound having an unsubstituted or substituted styryl and at least one amine (in one embodiment, an aromatic amine). The distyrylamine refers to a compound having two unsubstituted or substituted styryl groups and at least one amine (in one embodiment, an aromatic amine). The tristyrylamine refers to a compound having three unsubstituted or substituted styryl groups and at least one amine (in one embodiment, an aromatic amine). The tetrastyrylamine refers to a compound having four unsubstituted or substituted styryl groups and at least one amine (in one embodiment, an aromatic amine). An embodiment of styryl is distyryl, which can be further substituted. Correspondingly, the phosphines and ethers are defined similar to that of amines. An arylamine or aromatic amine refers to a compound having three unsubstituted or arbitrarily substituted aromatic ring or heterocyclic systems directly linked by nitrogen. At least one of these aromatic ring or heterocyclic systems can be selected from fused ring systems, which has at least 14 atoms in the aromatic ring. An embodiment thereof can be but not limited to aromatic anthracene amine, aromatic anthracenediamine, aromatic pyreneamine, aromatic pyrenediamine, aromatic chryseneamine and aromatic chrysenediamine. An aromatic anthraceneamine refers to a compound having one diarylamino group linked directly to an anthracene, in one embodiment, at position 9. An aromatic anthracenediamine refers to a compound having two diarylamino groups linked directly to an anthracene, in one embodiment, at positions 9, and 10. Definitions of aromatic pyreneamine, aromatic pyrenediamine, aromatic chryseneamine and aromatic chrysenediamine are similar, wherein, the diarylamino group can be lined to the pyrene at the position 1 or position 1 and 6.

A singlet emitter can be selected from indenofluorene-amine and indenofluorene-diamine, benzindenofluorene-amine and benzindenofluorene-diamine, dibenzindenofluorene-amine and dibenzindenofluorene-diamine, etc.

Other materials which can be used as the singlet emitter include but are not limited to polycyclic aromatic hydrocarbon compounds, especially the derivatives of the following compounds: anthracene such as 9,10-di(2-naphthanthracene), naphthalene, tetracene, xanthene, phenanthrene, pyrene (such as 2,5,8,11-tetra-t-butylpyrene), indenopyrene, phenylene such as (4,4′-di(9-ethyl-3-vinylcarbazole)-1,1′-biphenyl), diindenopyrene, decacyclene, coronene, fluorene, spirobifluorene, arylpyrene, arylene ethylene, cyclopentadiene such as tetraphenylcyclopentadiene, rubrene, coumarin, rhodamine, quinacridone, pyran such as 4(dicyanomethylene)-6-(4-p-dimethylaminostyryl-2-methyl)-4H-pyran (DCM), thiopyran, di(azinyl)imino boron compounds, bis(azinyl)methene compounds, carbostyryl compounds, pentoxazone, benzoxazole, benzothi azole, benzimidazole and diketopyrrolopyrrole.

Some examples of the singlet emitter are listed as follows but not limited thereto:

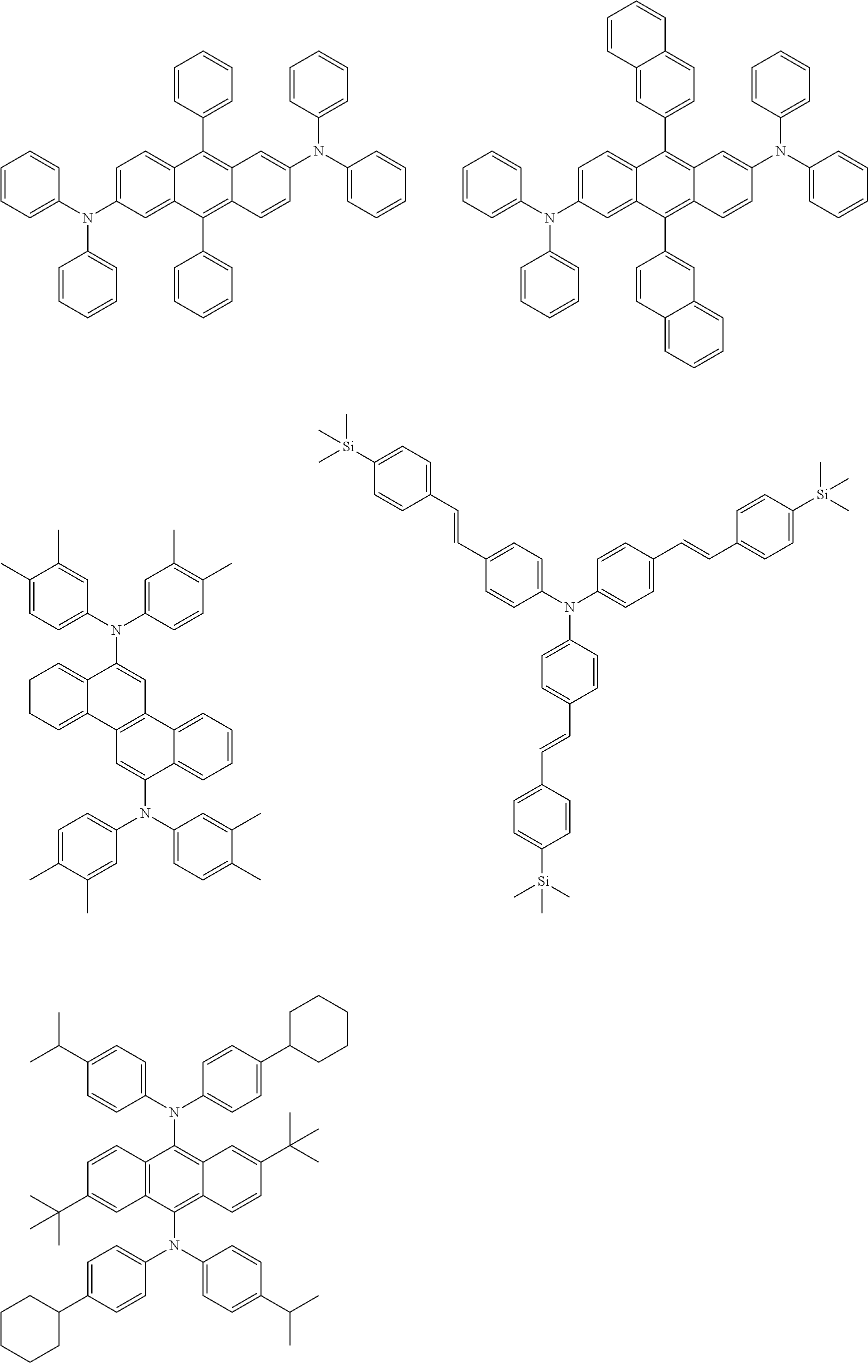

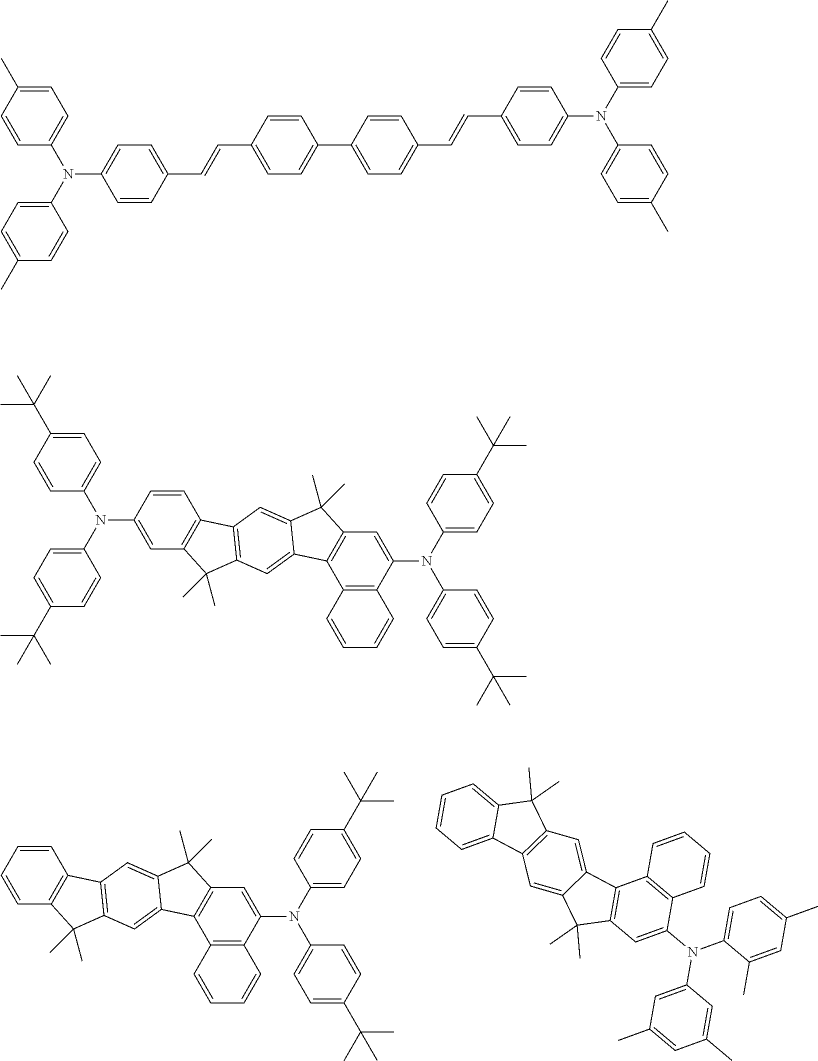

5. Thermally Activated Delayed Fluorescent Material (TADF)

Traditional organic fluorescent materials only can emit light by 25% of singlet excitons produced by electrical excitation, and the internal quantum efficiency of the device is low (up to 25%). Although intersystem-crossing of phosphorescent materials is enhanced due to a strong spin-orbit coupling at heavy atom centers, singlet excitons and triplet excitons formed by electrical excitation can be effectively used to emit light, and to achieve 100% internal quantum efficiency of the devices. However, problems of phosphorescent materials, such as, high cost, poor stability and serious rolling-off of devices, limit their application in OLEDs. Thermally activated delayed fluorescent materials are the third generation of organic light-emitting materials developed after organic fluorescent materials and organic phosphorescent materials. This kind of material generally has a small singlet-triplet energy level difference (ΔEst), so that triplet excitons can be converted to singlet excitons through reverse intersystem crossing to emit light. In this way, the singlet excitons and triplet excitons formed by the electrical excitation can be utilized fully and the internal quantum efficiency of devices can reach 100%.

The TADF material needs to have a relative small singlet-triplet energy level difference, generally ΔEst<0.3 eV, in one embodiment ΔEst<0.2 eV, in another embodiment ΔEst<0.1 eV, and in yet another embodiment ΔEst<0.05 eV. In one embodiment, TADF has better fluorescent quantum efficiency.

Examples of TADF light-emitting materials are listed in the following table, but are not limited thereto:

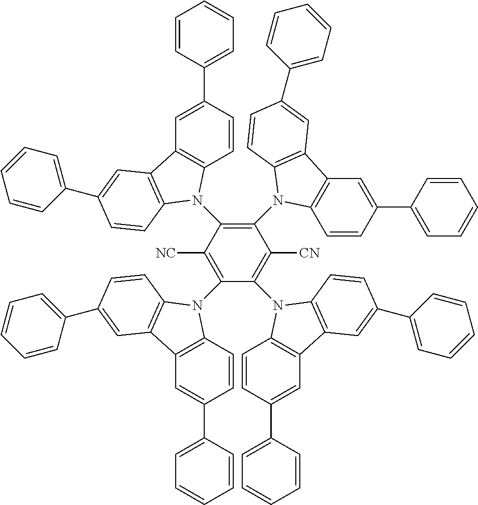 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

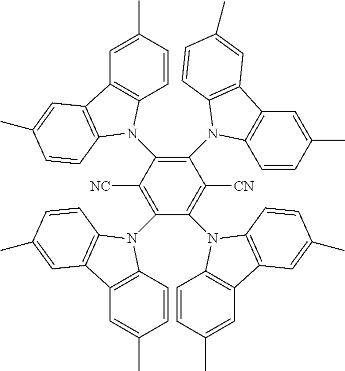

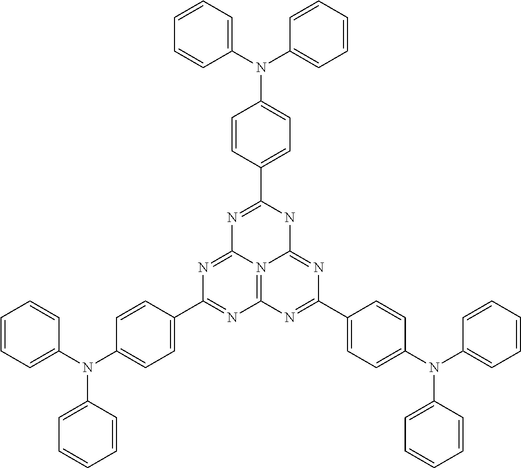

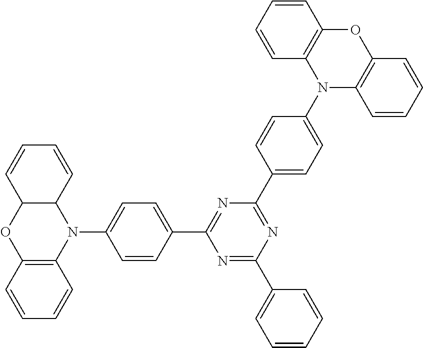 [SMILES: C1=CC2Oc3ccccc3N(c3ccc(-c4nc(-c5ccccc5)nc(-c5ccc(N6c7ccccc7Oc7ccccc76)cc5)n4)cc3)C2C=C1]

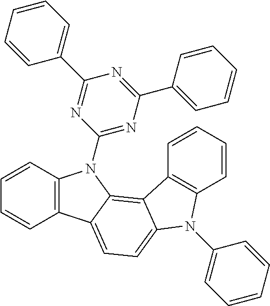 [SMILES: c1ccc(-c2nc(-c3ccccc3)nc(-n3c4ccccc4c4ccc5c(c6ccccc6n5-c5ccccc5)c43)n2)cc1]

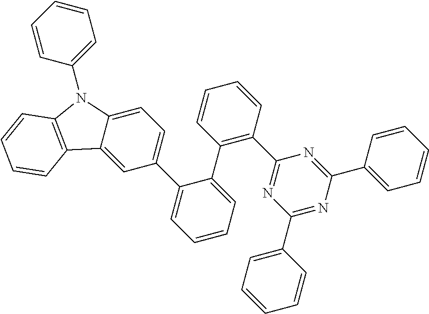 [SMILES: c1ccc(-c2nc(-c3ccccc3)nc(-c3ccccc3-c3ccccc3-c3ccc4c(c3)c3ccccc3n4-c3ccccc3)n2)cc1]

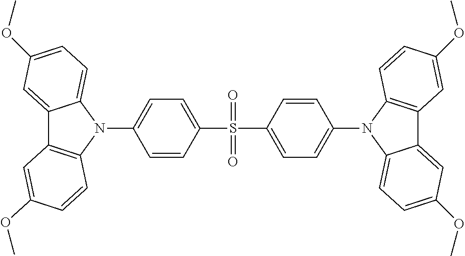 [SMILES: COc1ccc2c(c1)c1cc(OC)ccc1n2-c1ccc(S(=O)(=O)c2ccc(-n3c4ccc(OC)cc4c4cc(OC)ccc43)cc2)cc1]

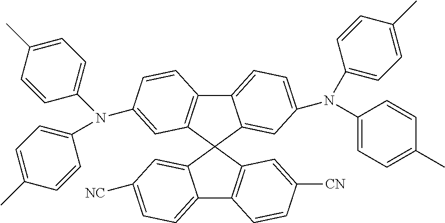

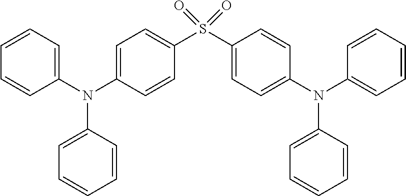 [SMILES: O=S(=O)(c1ccc(N(c2ccccc2)c2ccccc2)cc1)c1ccc(N(c2ccccc2)c2ccccc2)cc1]

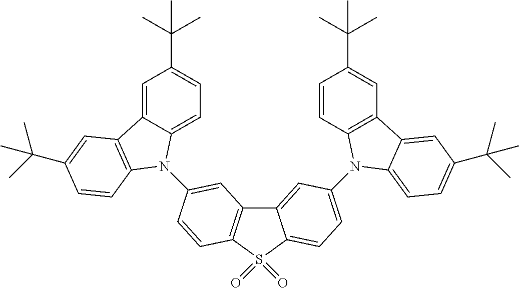 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O]

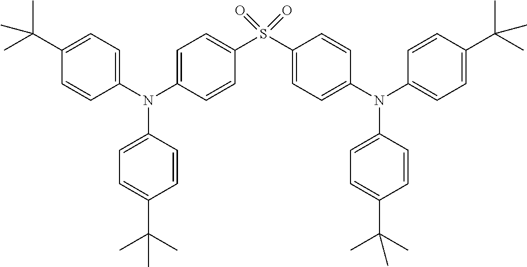 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

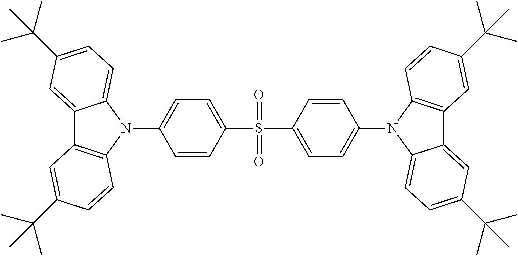 [SMILES: CC(C)(C)c1ccc2c(c1)c1cc(C(C)(C)C)ccc1n2-c1ccc(S(=O)(=O)c2ccc(-n3c4ccc(C(C)(C)C)cc4c4cc(C(C)(C)C)ccc43)cc2)cc1]

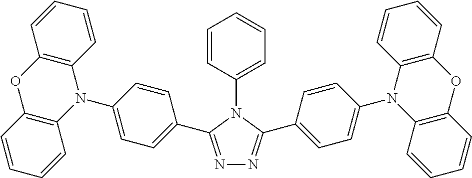 [SMILES: c1ccc(-n2c(-c3ccc(N4c5ccccc5Oc5ccccc54)cc3)nnc2-c2ccc(N3c4ccccc4Oc4ccccc43)cc2)cc1]

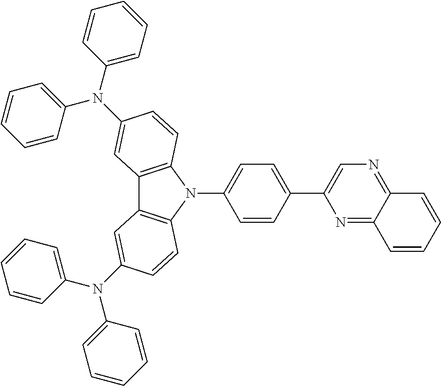 [SMILES: c1ccc(N(c2ccccc2)c2ccc3c(c2)c2cc(N(c4ccccc4)c4ccccc4)ccc2n3-c2ccc(-c3cnc4ccccc4n3)cc2)cc1]

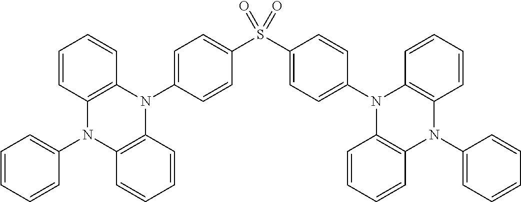 [SMILES: O=S(=O)(c1ccc(N2c3ccccc3N(c3ccccc3)c3ccccc32)cc1)c1ccc(N2c3ccccc3N(c3ccccc3)c3ccccc32)cc1]

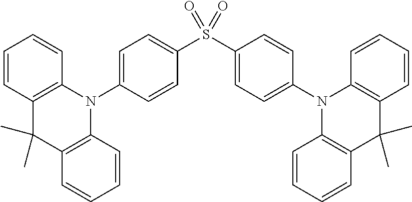

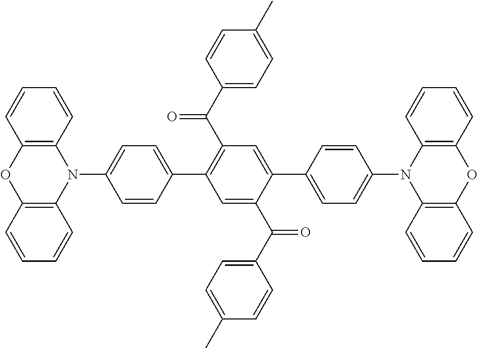 [SMILES: Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1]

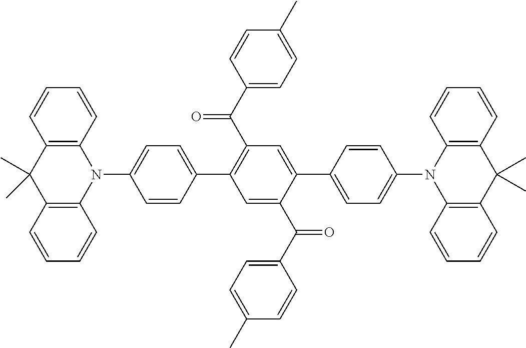

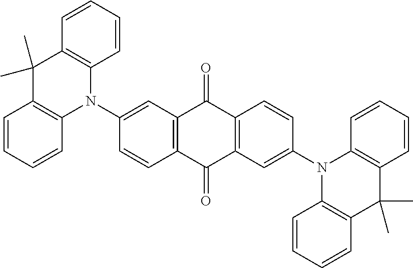

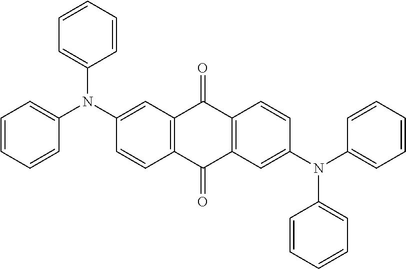 [SMILES: O=C1c2ccc(N(c3ccccc3)c3ccccc3)cc2C(=O)c2ccc(N(c3ccccc3)c3ccccc3)cc21]

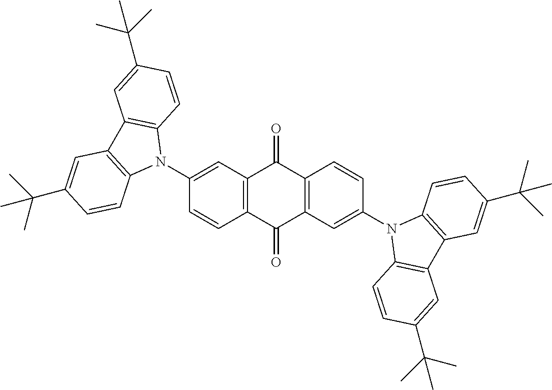 [SMILES: CC(C)(C)c1ccc2c(c1)c1cc(C(C)(C)C)ccc1n2-c1ccc2c(c1)C(=O)c1ccc(-n3c4ccc(C(C)(C)C)cc4c4cc(C(C)(C)C)ccc43)cc1C2=O]

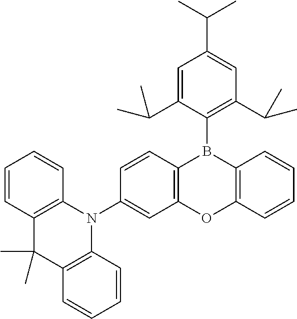 [SMILES: CC(C)c1cc(C(C)C)c(B2c3ccccc3Oc3cc(N4c5ccccc5C(C)(C)c5ccccc54)ccc32)c(C(C)C)c1]

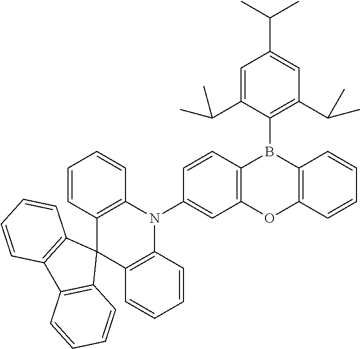 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1]

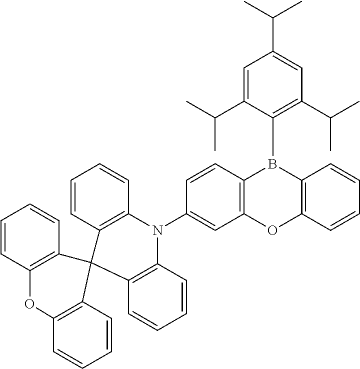 [SMILES: CC(C)c1cc(C(C)C)c(B2c3ccccc3Oc3cc(N4c5ccccc5C5(c6ccccc6Oc6ccccc65)c5ccccc54)ccc32)c(C(C)C)c1]

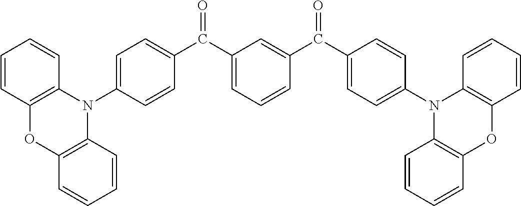 [SMILES: O=C(c1ccc(N2c3ccccc3Oc3ccccc32)cc1)c1cccc(C(=O)c2ccc(N3c4ccccc4Oc4ccccc43)cc2)c1]

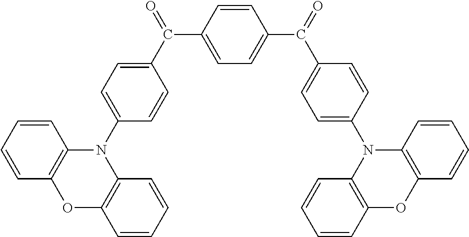 [SMILES: O=C(c1ccc(C(=O)c2ccc(N3c4ccccc4Oc4ccccc43)cc2)cc1)c1ccc(N2c3ccccc3Oc3ccccc32)cc1]

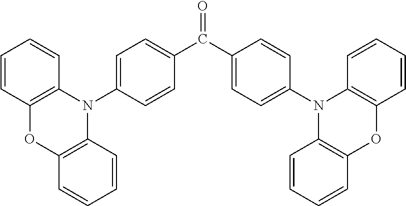 [SMILES: O=C(c1ccc(N2c3ccccc3Oc3ccccc32)cc1)c1ccc(N2c3ccccc3Oc3ccccc32)cc1]

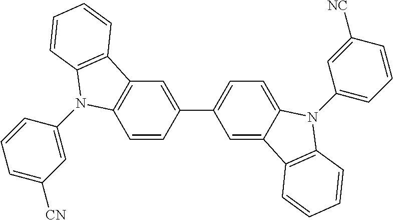 [SMILES: N#Cc1cccc(-n2c3ccccc3c3cc(-c4ccc5c(c4)c4ccccc4n5-c4cccc(C#N)c4)ccc32)c1]

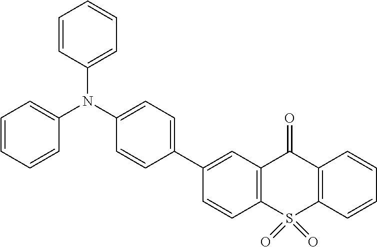 [SMILES: O=C1c2ccccc2S(=O)(=O)c2ccc(-c3ccc(N(c4ccccc4)c4ccccc4)cc3)cc21]

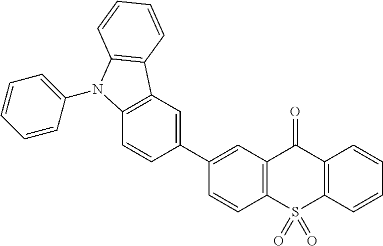 [SMILES: O=C1c2ccccc2S(=O)(=O)c2ccc(-c3ccc4c(c3)c3ccccc3n4-c3ccccc3)cc21]

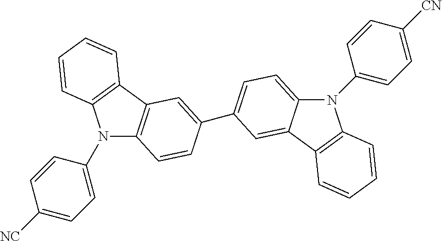 [SMILES: N#Cc1ccc(-n2c3ccccc3c3cc(-c4ccc5c(c4)c4ccccc4n5-c4ccc(C#N)cc4)ccc32)cc1]

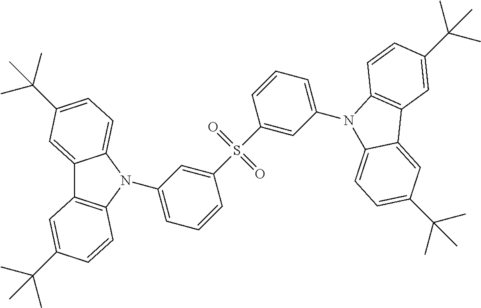 [SMILES: CC(C)(C)c1ccc2c(c1)c1cc(C(C)(C)C)ccc1n2-c1cccc(S(=O)(=O)c2cccc(-n3c4ccc(C(C)(C)C)cc4c4cc(C(C)(C)C)ccc43)c2)c1]

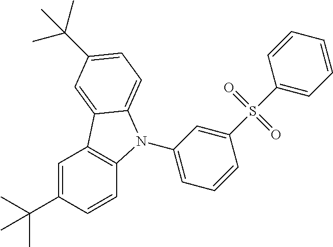 [SMILES: CC(C)(C)c1ccc2c(c1)c1cc(C(C)(C)C)ccc1n2-c1cccc(S(=O)(=O)c2ccccc2)c1]

6. Triplet Emitter

The triplet emitter is also called phosphorescent emitter. In one embodiment, the triplet emitter can be a metal complex of the general formula M(L)ₙ, wherein M is a metal atom; L on each occurrence can be same or different and is an organic ligand linked to or coordinated to the metal atom M at one or more positions; n is an integer greater than 1, in one embodiment is 1, 2, 3, 4, 5, or 6. Optionally, these metal complexes are linked to a polymer at one or more positions, in one embodiment via an organic ligand.

In one embodiment, the metal atoms M are selected from but not limited to transition metal elements, lanthanide elements, or actinide elements, in one embodiment can be Ir, Pt, Pd, Au, Rh, Ru, Os, Sm, Eu, Gd, Tb, Dy, Re, Cu or Ag, and in another embodiment can be Os, Ir, Ru, Rh, Re, Pd or Pt.

In one embodiment, the triplet emitters can contain a chelating ligand, i.e., a ligand coordinated with the metal via at least two binding sites. In one embodiment, the triplet emitter contains two or three identical or different bidentate ligand or polydentate ligands. The chelating ligand is beneficial to increase the stability of metal complex.

Examples of organic ligands can be selected from but are not limited to phenylpyridine derivatives, 7,8-benzoquinoline derivatives, 2(2-thienyl)pyridine derivatives, 2(1-naphthyl)pyridine derivatives or 2-phenylquinoline derivatives. All of these organic ligands can be substituted, for example, by fluoromethyl or trifluoromethyl. In one embodiment, an auxiliary ligand can be selected from acetylacetonate or picric acid.

In one embodiment, a metal complex that can be used as the triplet emitter has the following form:

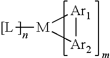

wherein M is a metal selected from transition metal elements, lanthanide elements, or actinide elements.

Ar¹ which is a cyclic group can be the same or different at each occurrence, the cyclic group contains at least one donor atom, i.e., one atom containing a lone pair electrons, such as N or P, via which the cyclic group is coordinated with the metal. Ar² which is a cyclic group can be the same or different at each occurrence, the cyclic group contains at least one C atom via which the cyclic group is linked to the metal. Ar¹ and Ar² are linked together through a covalent bond, each of which can carry one or more substituent groups, and they can also be linked together by a substituent group. L which is an auxiliary ligand can be the same or different at each occurrence, and in one embodiment is a bidentate chelating ligand, and in another embodiment, is a monoanion bidentate chelating ligand; m is 1, 2 or 3, in one embodiment is 2 or 3, in another embodiment is 3; n is 0, 1 or 2, in one embodiment is 0 or 1, in another embodiment is 0.

Examples of triplet emitter are listed in the following table, but are not limited thereto:

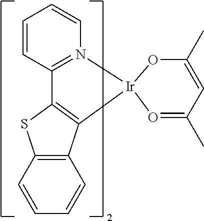

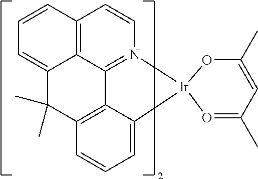

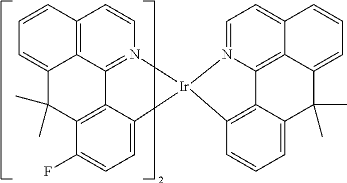

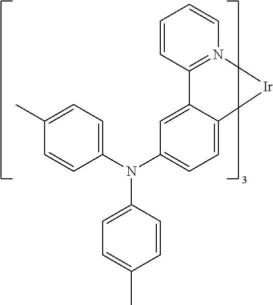

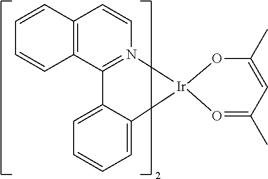

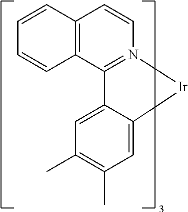

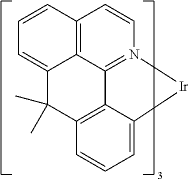

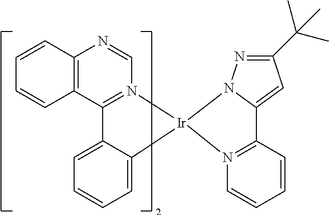

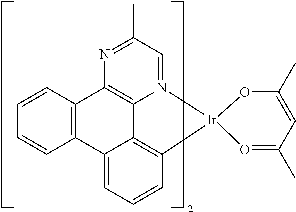

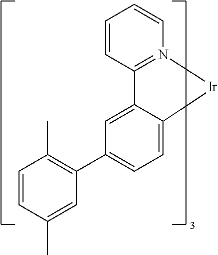

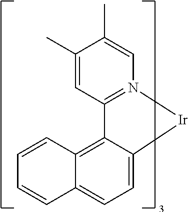

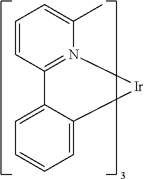

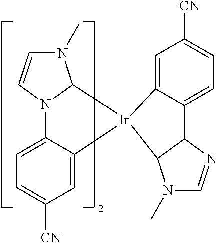

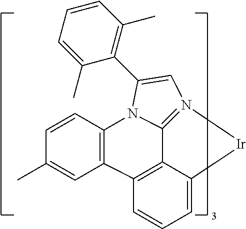

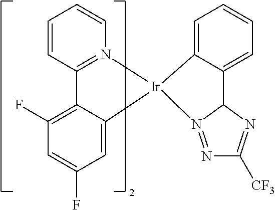

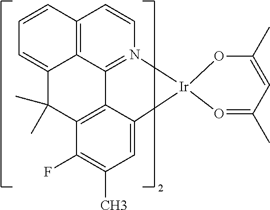

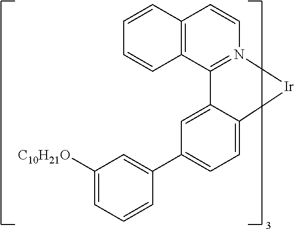

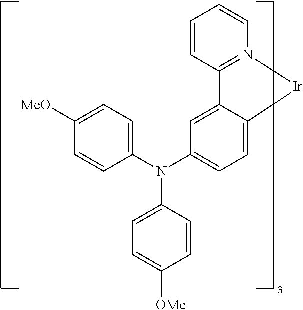

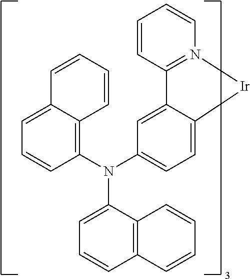

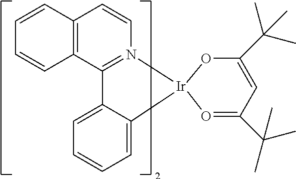

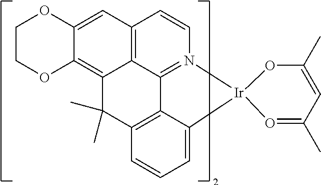

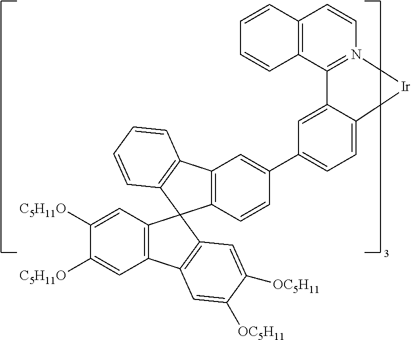

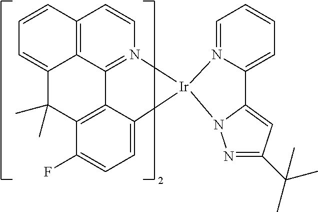

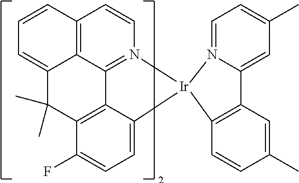

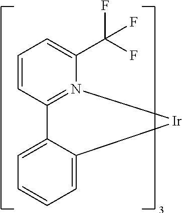

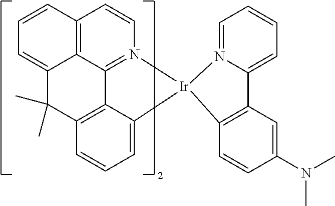

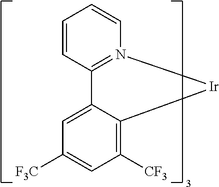

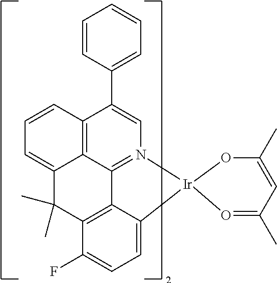

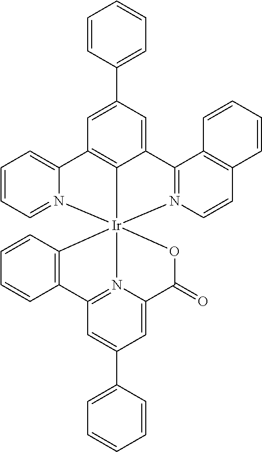

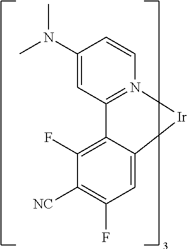

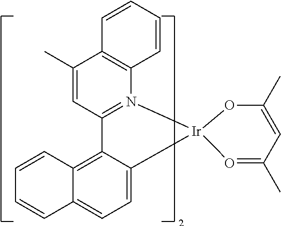

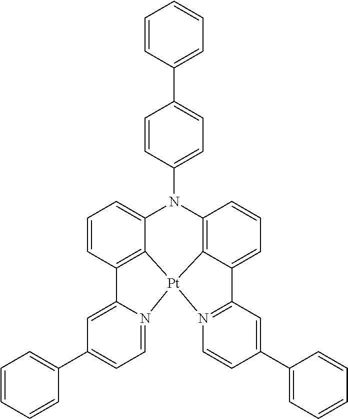

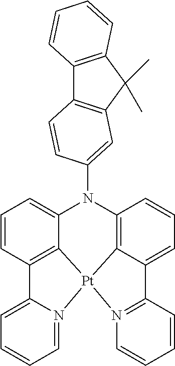

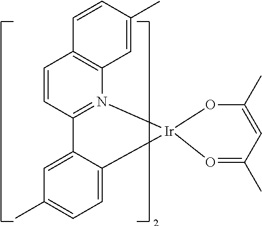

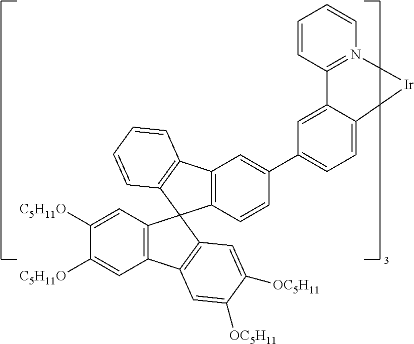

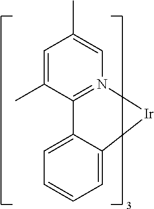

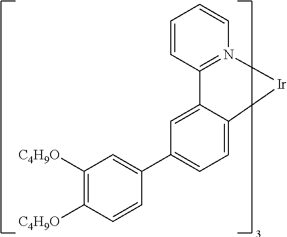

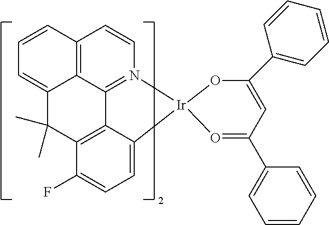

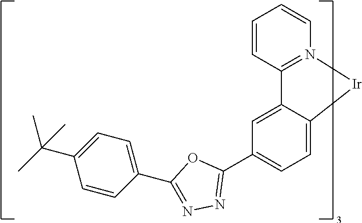

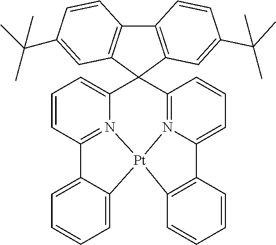

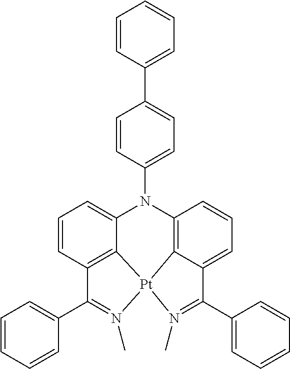

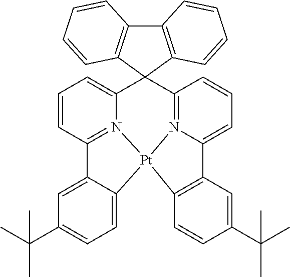

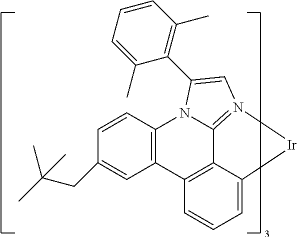

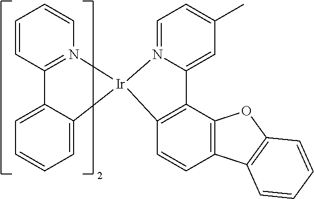

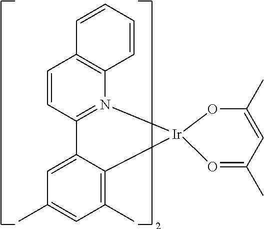

In another embodiment, the functional material contained in the formulation for printing electronic device of the present disclosure can be a polymer material.

In general, the small molecule organic functional material described above can include HIM, HTM, ETM, EIM, Host, fluorescent emitter, phosphorescent emitter, TADF, etc, and any of them can be contained in the polymer as a repeating unit.

In one embodiment, the polymer used for the present disclosure can be a conjugated polymer. In general, the conjugated polymer has the following general formula:

BₓA_{y} Chemical Formula 1

wherein when B and A appears many times, they can independently select a same or different structural unit.

B is a π-conjugate structural unit having a larger energy gap, also called a backbone unit, selected from monocyclic aryl or polycyclic aryl or heteroaryl, in one embodiment from benzene, biphenylene, naphthalene, anthracene, phenanthrene, dihydrophenanthrene, 9,10-dihydrophenanthrene, fluorene, difluorene, spirobifluorene, p-phenyl acetylene, trans-indenofluorene, cis-indenofluorene, dibenzo-indenofluorene, indenonaphthalene and derivatives thereof.

A is a π-conjugate structural unit has a smaller energy gap, also called a functional unit. According to different functional requirements, A can be selected from, but is not limited to structure units containing the hole injection or hole transport material (HIM/HTM), the electron injection or transport material (EIM/ETM), the host material (Host), the singlet emitter (fluorescence emitter), and the triplet emitter (phosphorescent emitter) described above.

x, y are greater than 0, and x+y=1.

In some embodiments, the functional material contained in the formulation for printing electronic device described of the present disclosure is polymer HTM.

In one embodiment, the polymer HTM material is a homopolymer, and the homopolymer can be selected from polythiophene, polypyrrole, polyaniline, polybiphenyl triarylamine, polyvinylcarbazole and derivatives thereof.

In another embodiment, the polymer HTM is a conjugated polymer represented by Chemical Formula 1, wherein

A is a functional group having hole transporting ability, which can be identically or differently selected from structural units containing the hole injection or transport material (HIM/HTM) described above. In one embodiment, A is selected from amine. biphenyltriarylamine, thiophene, and thiophthene such as dithienothiophene and thiophthene, pyrrole, aniline, carbazole, indenocarbazole, indolocarbazole, pentacene, phthalocyanine, porphyrin, and derivatives thereof.

x, y are greater than 0, and x+y=1; usually y≥10; in one embodiment y≥15, in another embodiment y≥20; in yet another embodiment x=y=0.5.

Examples of conjugated polymers that can be used as the HTM are listed below, but are not limited thereto:

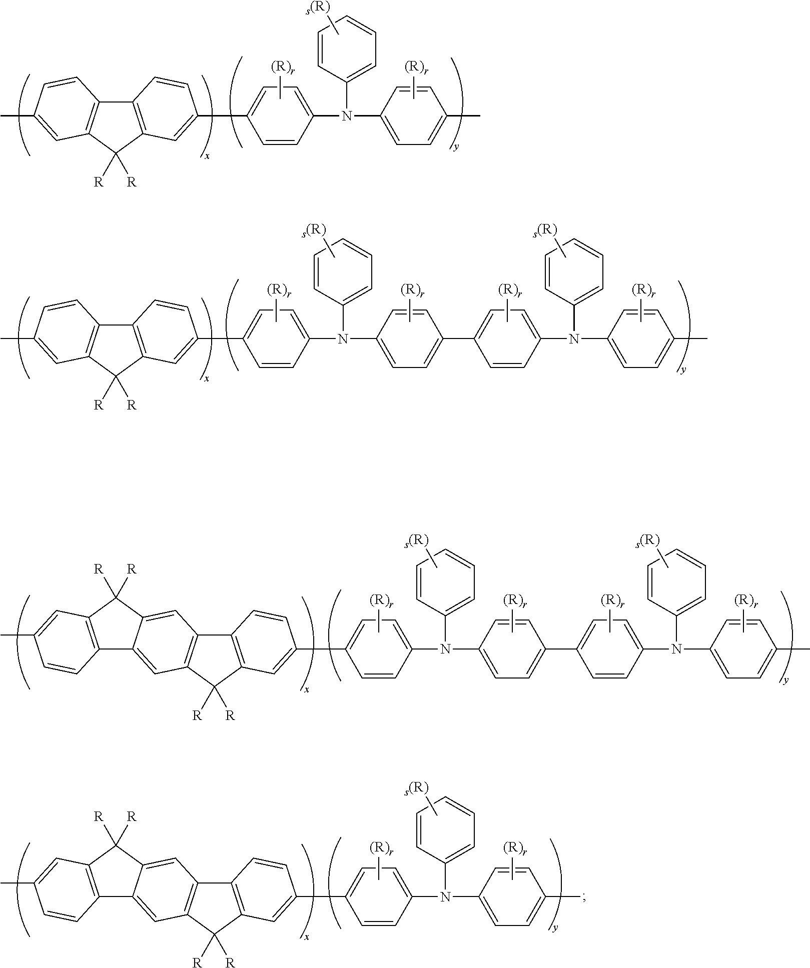

wherein each R is independently selected from hydrogen, straight-chain alkyl, straight-chain alkoxy, or straight-chain thioalkoxy each containing 1 to 20 C atoms, branched or cyclic alkyl, branched or cyclic alkoxy, branched or cyclic thioalkoxy, or branched or cyclic silyl each containing 3 to 20 C atoms, substituted keto containing 1 to 20 C atoms, alkoxycarbonyl containing 2 to 20 C atoms, aryloxycarbonyl containing 7 to 20 C atoms, cyano (—CN), carbamoyl (—C(═O)NH₂), haloformyl (—C(═O)-X, wherein X represents a halogen atom), formyl (—C(═O)—H), isocyano, isocyanate, thiocyanate, isothiocyanate, hydroxyl, nitro, CF₃, Cl, Br, F, crosslinkable group, substituted or unsubstituted aromatic or heteroaromatic ring system containing 5 to 40 ring atoms, or aryloxy or heteroaryloxy containing 5 to 40 ring atoms; wherein, one or more of the R groups and/or the R groups can form a monocyclic or polycyclic aliphatic or aromatic ring system with each other.

r is selected from 0, 1, 2, 3, or 4;

s is selected from 0, 1, 2, 3, 4, or 5;

x, y are greater than 0 and x+y =1; usually y≥10; in one embodiment y≥15, in another embodiment y≥20;in yet another embodiment x=y=0.5.

Another kind of organic functional material can be a polymer having electron transporting ability, including conjugated polymer and non-conjugated polymer.

An embodiment of polymer ETM can be a homopolymer selected from polyphenanthrene, polyphenanthroline, polyindenofluorene, polyspirobifluorene, polyfluorene, and derivatives thereof.

A preferable polymer ETM can be a conjugated polymer represented by Chemical Formula 1, and when A appears many times, A can be identically or differently selected from forms:

A is functional group having electron transport ability and can be selected from tris(8-hydroxyquinoline) aluminium (AlQ3), benzene, biphenylene, naphthalene, anthracene, phenanthrene, dihydrophenanthrene, fluorene, bifluorene, spirobifluorene, p-phenyl acetylene, pyrene, perylene, 9,10-dihydrophenanthrene, phenazine, phenanthroline, trans-indenofluorene, cis-indenofluorene, dibenzo-indenofluorene, indenonaphthalene, benzoanthracene and derivatives thereof.

x, y are greater than 0, and x+y=1; usually y≥10; in one embodiment y≥15, in another embodiment y≥20; in yet another embodiment x=y=0.5.

In another embodiment, the functional material contained in the formulation for printing electronic device described of the present disclosure is luminescent polymer.

In another embodiment, the luminescent polymer is a conjugated polymer having a following general formula:

BₓA₁_{y}A₂_{z} Chemical formula 2

B has the same definition as it in Chemical Formula 1.

A₁ is a functional group having hole or electron transpot ability, and can be selected from, but is not limited to the structural units containing the hole injection or transport material (HIM/HTM) or electron injection or transport material(EIM/ETM) described above.

A₂ is functional group having light-emitting ability, and can be selected from, but is not limited to the structural units containing singlet emitter (fluorescent emitter) and triplet emitter (phosphorescent emitter).

x, y, z are greater than 0, and x+y+z=1.

In another embodiment, the polymer used for the present disclosure can be a non-conjugated polymer. The non-conjugated polymer can be a backbone with all functional groups on side chains. Examples of the non-conjugated polymers can be selected from, but are not limited to, non-conjugated polymer used as a phosphorescent host or a phosphorescent emitting material, and a non-conjugated polymer used as a fluorescent emitting material. In addition, the non-conjugated polymer can also be a polymer in which conjugated functional units on the backbone are linked together by non-conjugated linking units.

The present disclosure further relates to a method for preparing a film of a functional material, wherein disposing the above formulation for printing electronic device on a substrate is by printing or coating, and the printing or coating methods can be selected from (but are not limited to) inkjet printing, nozzle printing, typographic printing, screen printing, dip coating, spin coating, blade coating, roller printing, torsion roller printing, lithographic printing, flexographic printing, rotary printing, spray coating, brush coating, pad printing, or slot die coating, etc.

In one embodiment, the film containing the functional material is prepared by inkjet printing. Ink jet printers that can be used to print the ink of the present disclosure can be commercially available printers and include drop-on-demand printheads. Those printers can be bought from such as Fujifilm Dimatix (Lebanon, N. H.), Trident International (Brookfield, Conn.), Epson (Torrance, Calif.), Hitachi Data systems Corporation (Santa Clara, Calif.), Xaar PLC (Cambridge, United Kingdom), and Idanit Technologies, Limited (Rishon Le Zion, Isreal). For instance, the present disclosure uses Dimatix Materials Printer DMP-3000 (Fujifilm) to print.

The disclosure further relates to an electronic device comprising one or more layers of functional films, wherein at least one layer of the functional film is prepared by using the printing ink formulation of the disclosure described in the present disclosure, in particular prepared by method of printing or coating.

Examples of electronic device include but are not limited to, a quantum dot light emitting diode (QLED), a quantum dot photovoltaic cell (QPV), a quantum dot light emitting electrochemical cell (QLEEC), a quantum dot field effect transistor (QFET), a quantum dot light emitting field effect transistor, quantum dot laser, a quantum dot sensor, an organic light emitting diode (OLED), an organic photovoltaic cell (OPV), an organic light emitting electrochemical cell (OLEEC), an organic field effect transistor (OFET), an organic luminescent field effect transistor, an organic laser, an organic sensor, etc.

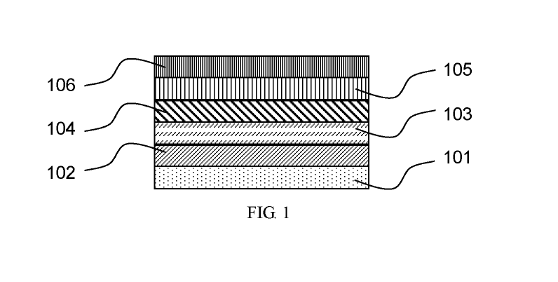

In one embodiment, the above electronic device is an electroluminescent device or a photovoltaic cell, as shown in FIG. 1, which includes a substrate 101, an anode 102, at least one light emitting layer or light-absorbing layer 104, and a cathode 106. Following description only takes an electroluminescent device as an example.

The substrate 101 can be opaque or transparent. A transparent substrate can be used to manufacture a transparent light emitting device. The substrate can be rigid or elastic. The substrate can be plastic, metal, semiconductor wafer or glass. In one embodiment, the substrate has a smooth surface. A substrate with a defect-free surface is a particularly desirable choice. In one embodiment, the substrate can be selected from a polymer film or a plastic, the glass transition temperature Tg of which is 150° C. or above, in one embodiment higher than 200° C., in another embodiment higher than 250° C., and in yet another embodiment higher than 300° C. Examples of the substrate include poly(ethylene terephthalate) (PET) and polyethyleneglycol(2, 6-naphthalene) (PEN), but are not limited thereto.

The anode 102 can include a conducting metal or a metal oxide, or a conducting polymer. The anode can inject hole easily to the HIL or the HTL or the light emitting layer. In one embodiment, the absolute value of difference between the work function of the anode and the HOMO level or the valence band level of the p-type semiconductor material as HIL or HTL is smaller than 0.5 ev, in one embodiment smaller than 0.3 ev, and in another embodiment smaller than 0.2 ev. Examples of the anode material include but are not limited to Al, Cu, Au, Ag, Mg, Fe, Co, Ni, Mn, Pd, Pt, ITO, Al-doped zinc oxide (AZO), etc. Other suitable anode materials are known, and a person having general technical knowledge in the art can select and use them easily. The anode material can be deposited by any suitable technology, such as by a suitable physical vapor deposition method including radio-frequency magnetron sputtering, vacuum thermal evaporation, e-beam, etc.

In some embodiments, the anode has a patterned structure. A patterned ITO conducting substrate available on the market can be utilized to manufacture a device of the present disclosure.

The cathode 106 can include a conducting metal or a metal oxide. The cathode can inject electron easily to the EIL or the ETL or the light emitting layer. In one embodiment, the absolute value of difference between the work function of the cathode and the LUMO level or the conduction band level of the n-type semiconductor material as EIL or ETL or HBL is smaller than 0.5 ev, in one embodiment smaller than 0.3 ev, and in another embodiment smaller than 0.2 ev. In principle, all of the materials for use in a cathode of OLED can be used as the cathode material of the device in the present disclosure. Examples of the cathode material include but are not limited to Al, Au, Ag, Ca, Ba, Mg, LiF/Al, MgAg alloy, BaF₂/Al, Cu, Fe, Co, Ni, Mn, Pd, Pt, ITO, etc. The cathode material can be deposited by any suitable technology, such as by a suitable physical vapor deposition method including radio-frequency magnetron sputtering, vacuum thermal evaporation, e-beam, etc.

The light emitting layer 104 can at least include one layer of luminescent functional material in a thickness between 2 nm and 200 nm. In one embodiment, the light emitting device of the present disclosure includes a light emitting layer printed from the printing ink of the present disclosure, wherein the printing ink includes at least one luminescent functional material describe above, particularly the quantum dots or the organic functional materials.

In one embodiment, the light emitting device of the present disclosure can further include a hole injection layer (HIL) or a hole transport layer (HTL) 103 including the organic HTM or the inorganic p-type material described above. In one embodiment, the HIL or the HTL can be printed from the printing ink of the present disclosure, wherein the printing ink includes a functional material having hole transport ability, particularly quantum dots or organic HTM material.

In another embodiment, the light emitting device of the present disclosure can further include an electron injection layer (EIL) or an electron transport layer (ETL) 105 such as the organic ETM or the inorganic n-type material described above. In some embodiments, the EIL or the ETL can be printed from the printing ink of the present disclosure, wherein the printing ink includes a functional material having electron transport ability, particularly the quantum dots or the organic ETM.

The present disclosure further relates to a use of the light emitting device of the present disclosure in various situations, including but not limited to various display devices, backlight units, lighting sources, etc.

The present disclosure will be described below with reference to some embodiments, but the present disclosure is not limited to the following embodiments. It should be understood that the appended claims summarized the scope of the present disclosure. Under the guiding of the concept of the present disclosure, those skilled in the art should be aware that certain changes to the various embodiments of the present disclosure should be covered by the spirit and the scope of the claims of the present disclosure.

### EXAMPLES

### Example 1

### Preparation of Quantum Dots as a Blue Emitter (CdZnS/ZnS)

A first solution for use is prepared through adding 0.0512 g of S and 2.4 mL of ODE in a single-neck flask with a capacity of 25 mL, and heating to 80° C. in an oil bath to dissolve S. A second solution for use is prepared through adding 0.1280 g of S and 5 mL of OA in a single-neck flask with a capacity of 25 mL, and heating to 90° C. in an oil bath to dissolve S. After that, 0.1028 g of CdO, 1.4680 g of zinc acetate and 5.6 mL of OA are added to a three-neck flask with a capacity of 50 mL, which is subsequently placed in a heating jacket with a capacity of 150 mL in a state that the necks at both sides are blocked by rubber stoppers and the upper side is connected to a condenser, and the conderser is connected to a double manifold at the other side. The three-neck flask is heated to 150° C., vacuumized for 40 min, and then purged with nitrogen gas. Then, 12 mL of ODE is injected into the three-neck flask by an injector. When the mixture in the three-neck flask is heated to 310° C., 1.92 mL of the first solution is injected quickly into the three-neck flask via an injector, and the time is counted up to 12 min. Once reaching 12 min, 4 mL of the second solution is dropwise added to the three-neck flask by an injector at a speed of about 0.5 mL/min. The reaction is stopped after 3 h, and the three-neck flask is placed in water immediately to be cooled to 150° C.

An excessive amount of hexane is added to the three-neck flask. The liquid in the three-neck flask is transferred to several centrifuge tubes with a capacity of 10 mL and subsequently treated by performing centrifugation and removing of the lower precipitation for three times. The liquid after post treatment 1 is added with acetone until precipitate occurs, after which centrifugation is performed and the supernatant liquid is removed to obtain the precipitate. The precipitate is dissolved with hexane again and then added with acetone until precipitate occurs, after which centrifugation is performed and the supernatant liquid is removed to obtain the precipitate, and the above steps are repeated for three times. Finally, the precipitate is dissolved with toluene and transferred to a glass vessel for storage

### Example 2

### Preparation of Quantum Dots as a Green Emitter (CdZnSeS/ZnS)

A first solution for use is prepared through adding Se 0.0079 g and S 0.1122 g in a single-neck flask with a capacity of 25 mL, metering 2 mL of TOP, purging nitrogen and stirring. After that, 0.0128 g of CdO, 0.3670 g of zinc acetate and 2.5 mL of OA are added to a three-neck flask with a capacity of 25 mL, of which the necks at both sides are blocked by rubber stoppers and the upper side is connected to a condenser that is connected to a double manifold at the other side. The three-neck flask is subsequently placed in a heating jacket with a capacity of 50 mL and subjected to the following steps of being vacuumized, purged with nitrogen, heated to 150° C., vacuumized for 30 min, injected with 7.5 mL of ODE, heated again to 300° C., injected quickly with 1 mL of the first solution, and kept for 10 min. Once reaching 10 min, the reaction is stopped immediately, and the three-neck flask is placed in water for cooling.

Afterwards, 5 mL of hexane is added to the three-neck flask. The mixed liquid is transferred to several centrifuge tubes of 10 mL and added with acetone until precipitate occurs, after which centrifugation is performed and the supernatant liquid is removed to obtain the precipitate. The precipitate is dissolved with hexane and then added with acetone until precipitate occurs, after which centrifugation is performed, and the above steps are repeated for three times. Finally, the precipitate is dissolved with a small amount of toluene and transferred to a glass vessel for storage.

### Example 3

### Preparation of Quantum Dots as a Red Emitter (CdSe/CdS/ZnS)

Cd(OA)₂ precursor is prepared through adding 1 mmol of CdO, 4 mmol of OA and 20 ml of ODE to a three-neck flask with a capacity of 100 ml, purging nitrogen and heating to 300° C. At this temperature, 0.25 mL of TOP dissolved with 0.25 mmol of Se powder is injected to the flask quickly. The reaction solution is reacted at this temperature for 90 sec to grow a CdSe core sized of about 3.5 nm. The reaction solution is added dropwise with 0.75 mmol of octanethiol at 300° C., and reacted for 30 min to grow a CdS shell in a thickness of about 1 nm. After that, the reaction solution is added dropwise with 4 mmol of Zn(OA)₂ and 2 mL of TBP dissolved with 4 mmol of S powder to grow a ZnS shell in a thickness of about 1 nm. After being reacted for 10 min, the reaction solution is cooled to the room temperature.

Afterwards, 5 mL of hexane is added to the three-neck flask. The mixed liquid is transferred to several centrifuge tubes of with a capacity of 10 mL and added with acetone until precipitate occurs, after which centrifugation is performed and the supernatant liquid is removed to obtain the precipitate. The precipitate is dissolved with hexane and then added with acetone until precipitate occurs, after which centrifugation is performed, and the above steps are repeated for three times. Finally, the precipitate is dissolved with a small amount of toluene and transferred to a glass vessel for storage.

### Example 4

### Preparation of ZnO Nanoparticles

A first solution is prepared by adding 1.475 g of zinc acetate in 62.5 mL of methanol. A second solution is prepared by dissolving 0.74g of KOH in 32.5 mL of methanol. The first solution is heated to 60° C. and stirred intensively. The second solution is added dropwise to the first solution by a sample injector, after which the mixed solution system is continuously stirred at 60° C. for 2 h. The heating source is removed and the solution system is kept quietly for 2 h. The reaction solution is washed by centrifugation for at least three times under the centrifugal condition of 4500 rpm for 5 min, and the white solid obtained finally is ZnO nanoparticles having a diameter of about 3 nm.

### Example 5

### Preparation of Quantum Dot Printing Ink Including Cyclohexylbenzene

An agitator is placed in a vial, which is washed cleanly and transferred to a glove box. 9.5 g of the cyclohexylbenzene solvent is prepared in the vial. Quantum dots are separated from a solution by using acetone to obtain quantum dot solid after centrifugation. The quantum dot solid of 0.5 g is weighed in the glove box and added to the solvent system in the vial, stirred at 60° C. till the quantum dots dispersed completely, and cooled to the room temperature. The resulting quantum dot solution is filtered by a 0.2 μm PTFE membrane, and then sealed and stored.

### Example 6

### Preparation of ZnO Nanoparticle Printing Ink Including 1,1′-bicyclohexane

An agitator is placed in a vial, which is washed cleanly and transferred to a glove box. 9.5 g of 1,1′-bicyclohexane solvent is prepared in the vial. 0.5 g of ZnO nanoparticle solid is weighed in the glove box and added to the solvent system in the vial, stirred at 60° C. till ZnO nanoparticles are dispersed completely, and cooled to the room temperature. The resulting ZnO nanoparticle solution is filtered by a 0.2 μm PTFE membrane, and then sealed and stored.

All the functional organic materials involved in the following examples are available commercially such as from Jilin OLED Material Tech Co., Ltd (www.jl-oled.com), or synthesized by a method reported in the literature.

### Example 7

### Preparation of Printing Ink for Organic Light Emitting Layer Including γ-valerolactone

In this example, the organic functional material of the light emitting layer includes a phosphorescent host material and a phosphorescent emitter material, wherein the phosphorescent host material is selected from a derivative of carbazole as follows:

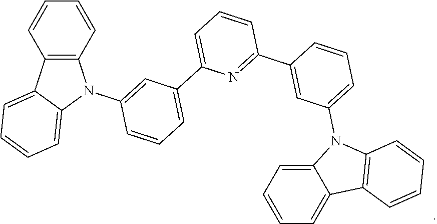 [SMILES: c1cc(-c2cccc(-c3cccc(-n4c5ccccc5c5ccccc54)c3)n2)cc(-n2c3ccccc3c3ccccc32)c1]

And the phosphorescent emitter material is selected from an iridium complex as follows:

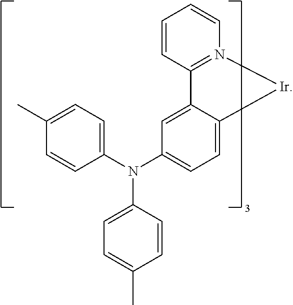

An agitator is placed in a vial, which is washed cleanly and transferred to a glove box. 9.8 g of the γ-valerolactone solvent is prepared in the vial. 0.18 g of the phosphorescent host material and 0.02 g of the phosphorescent emitter material are weighed in the glove box and added to the solvent system in the vial. The mixture is stirred at 60° C. till the organic compound is dispersed completely, and then the mixture is cooled to the room temperature. The resulting organic compound solution is filtered by a 0.2 μm PTFE membrane, and then sealed and stored.

### Example 8

### Preparation of Printing Ink for Organic Light Emitting Layer Including 2,4-dimethylsulfolane

In this example, the organic functional material of the light emitting layer includes a fluorescent host material and a fluorescent emitter material, wherein the fluorescent host material is selected from a derivative of spirofluorene as follows:

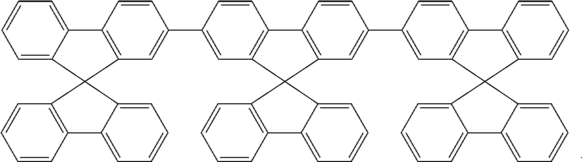 [SMILES: c1ccc2c(c1)-c1ccccc1C21c2ccccc2-c2ccc(-c3ccc4c(c3)C3(c5ccccc5-c5ccccc53)c3cc(-c5ccc6c(c5)C5(c7ccccc7-c7ccccc75)c5ccccc5-6)ccc3-4)cc21]

And the fluorescent emitter material is selected from the following compound:

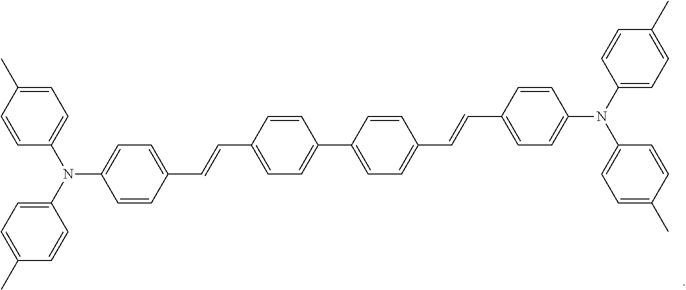 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

An agitator is placed in a vial, which is washed cleanly and transferred to a glove box. 9.8 g of the 2,4-dimethylsulfolane solvent is prepared in the vial. 0.19 g of the fluorescent host material and 0.01 g of the fluorescent emitter material are weighed in the glove box and added to the solvent system in the vial. The mixture is stirred at 60° C. till the functional organic material is dissolved completely, and the mixture is cooled to the room temperature. The resulting functional organic material solution is filtered by a 0.2 μm PTFE membrane, and then sealed and stored

### Example 9

### Preparation of Printing Ink for Organic Light Emitting Layer Including Fenchone

In this example, the organic functional material of the light emitting layer includes a host material and a TADF material, wherein the host material is selected from a compound having the following structure:

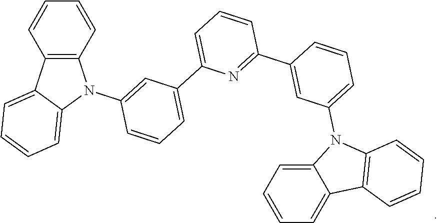 [SMILES: c1cc(-c2cccc(-c3cccc(-n4c5ccccc5c5ccccc54)c3)n2)cc(-n2c3ccccc3c3ccccc32)c1]

And the TADF material is selected from a compound having the following structure:

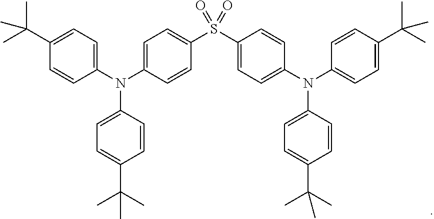 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

An agitator is placed in a vial, which is washed cleanly and transferred to a glove box. 9.8 g of a solvent of fenchone is prepared in the vial. 0.19 g of the host material and 0.01 g of the TADF material are weighed in the glove box and added to the solvent system in the vial. The mixture is stirred at 60° C. till the functional organic material dissolved completely, and the mixture is cooled to the room temperature. The resulting functional organic material solution is filtered by a 0.2 μm PTFE membrane, and then sealed and stored.

### Example 10

### Preparation of Hole Transport Material Printing Ink Including Sulfolane

In this example, the printing ink includes a hole transport layer material having hole transport ability.

The hole transport material is selected from a derivative of triarylamine as follows:

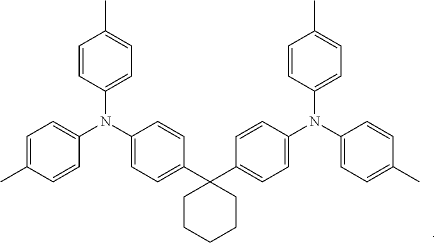

An agitator is placed in a vial, which is washed cleanly and transferred to a glove box. 9.8 g of a sulfolane solvent is prepared in the vial. 0.2 g of the hole transport material is weighed in the glove box and added to the solvent system in the vial. The mixture is stirred at 60° C. till the organic compound dispersed completely, and the mixture is cooled to the room temperature. The resulting organic compound solution is filtered by a 0.2 μm PTFE membrane, and then sealed and stored.

### Example 11

### Viscosity and Surface Tension Tests

The viscosity of the functional material ink is measured by DV-I Prime Brookfield rheometer, and the surface tension of the functional material ink is measured by SITA bubble pressure tensiometer.

According to the above tests, the viscosity and surface tension data of the functional material inks prepared in Example 5 to Example 10 are listed in the following table:

| Example | Viscosity (cPs) | Surface Tension (dyne/cm) |
|---|---|---|
| 5 | 5.1 ± 0.5 | 32.5 ± 0.3 |
| 6 | 4.8 ± 0.5 | 31.8 ± 0.3 |
| 7 | 4.6 ± 0.5 | 28.8 ± 0.5 |
| 8 | 8.7 ± 0.5 | 27.2 ± 0.3 |
| 9 | 4.7 ± 0.5 | 29.8 ± 0.5 |
| 10 | 10.5 ± 0.3 | 33.5 ± 0.3 |

### Example 12

### Preparation of a Functional Layer of Electronic Device with the Printing Ink of the Present Disclosure

A functional layer such as a light emitting layer and a charge transport layer of a light emitting diode can be prepared from the printing ink of the present disclosure through inkjet printing, wherein the printing ink utilizes the alicyclic solvent system and includes the functional material.

And the printing method includes the steps of: charging the ink including the functional material in an ink cartridge, which is equipped in an inkjet printer such as Dimatix Materials Printer DMP-3000 (Fujifilm); and regulating the waveform, pulse time and voltage for jetting the ink so as to optimize jetting of the ink and realize stability from inkjetting. A method for manufacturing an QLED device including a functional material film as a light emitting layer includes utilizing a piece of glass in a thickness of 0.7 mm that is sputtered with indium tin oxide (ITO) electrode patterns as a substrate of QLED. A pixel defining layer is patterned on the ITO to form holes for depositing the printing ink inside. Then the HIL/HTL material is jetted to the holes, and dried at high temperature in a vacuum to remove solvent to obtain an HIL/HTL film. After that, the printing ink including luminescent functional material is jetted to the HIL/HTL film, and dried at high temperature in a vacuum to remove solvent to obtain a film of light emitting layer. The printing ink including functional material having electron transport ability is jetted to the film of light emitting layer and dried at high temperature in a vacuum to remove solvent to obtain an electron transport layer (ETL). When utilizing the organic electron transport material, the ETL also can be formed by vacuum thermal evaporation, and finally the QLED device is packaged.

What described above are several embodiments of the present disclosure, and they are specific and in details, but not intended to limit the scope of the present disclosure. It will be understood by those skilled in the art that various modifications and improvements can be made without departing from the concept of the present disclosure, and all these modifications and improvements are within the scope of the present disclosure. The scope of the present disclosure shall be subject to the claims attached.

1. A formulation for printing electronic device comprising at least one functional material and a solvent system containing at least one organic solvent based on alicyclic structure and having general formula (I): 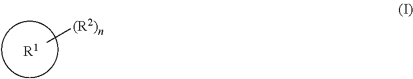
wherein R¹ is an alicyclic or heteroalicylic structure having 3 to 20 ring atoms; n is an integer greater than or equal to 0, and R² is a substituent when n≥1;
the boiling point of the organic solvent is ≥150° C., and the organic solvent is capable of being evaporated from the solvent system to form a functional material film.

2. The formulation for printing electronic device of claim 1, wherein the organic solvent based on alicyclic structure and having general formula (I) has a viscosity from 1 cPs to 100 cPs at 25° C.

3. The formulation for printing electronic device of claim 1, wherein the organic solvent based on alicyclic structure and having general formula (I) has a surface tension from 19 dyne/cm to 50 dyne/cm at 25° C.

4. The formulation for printing electronic device of claim 3, wherein R¹ of the organic solvent based on alicyclic structure and having general formula (I) has a structure selected from any one of general formulas shown below: 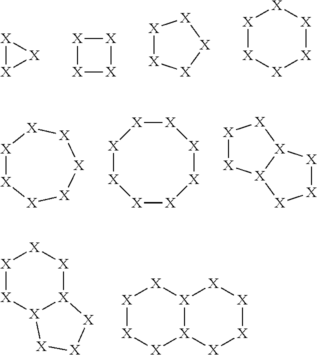
wherein X is selected from CR³R⁴, C(═O), S, S(═O)₂, O, SiR⁵R⁶, NR⁷, or P(═O) R⁸; each R³, R⁴, R⁵, R⁶, R⁷, R⁸ is independently selected from any one of the following: H, D, straight-chain alkyl, straight-chain alkoxy, or straight-chain thioalkoxy each containing 1 to 20 C atoms, branched or cyclic alkyl, branched or cyclic alkoxy, branched or cyclic thioalkoxy, or branched or cyclic silyl each containing 3 to 20 C atoms, substituted keto containing 1 to 20 C atoms, alkoxycarbonyl containing 2 to 20 C atoms, aryloxycarbonyl containing 7 to 20 C atoms, cyano (—CN), carbamoyl (—C(═O)NH₂), haloformyl (—C(═O)-X, wherein X represents a halogen atom), formyl (—C(═O)—H), isocyano, isocyanate, thiocyanate, isothiocyanate, hydroxyl, nitro, CF₃, Cl, Br, F, crosslinkable group, substituted or unsubstituted aromatic or heteroaromatic ring system containing 5 to 40 ring atoms, or aryloxy or heteroaryloxy containing 5 to 40 ring atoms; wherein when one or some of R³, R⁴, R⁵, R⁶, R⁷, R⁸ exist simultaneously, they exist independently, or form a monocyclic or polycyclic aliphatic or aromatic ring system with each other and/or with R¹ or R².

5. The formulation for printing electronic device of claim 1, wherein each R² contained in the organic solvent based on alicyclic structure and having general formula (I) is identically or differently selected from any one of the following: straight-chain alkyl, straight-chain alkoxy or straight-chain thioalkoxy each containing 1 to 20 C atoms, branched or cyclic alkyl, branched or cyclic alkoxy, branched or cyclic thioalkoxy or silyl each containing 3 to 20 C atoms, substituted keto containing 1 to 20 C atoms, alkoxycarbonyl containing 2 to 20 C atoms; aryloxycarbonyl containing 7 to 20 C atoms, cyano (—CN), carbamoyl (—C(═O)NH₂), haloformyl (—C(═O)-X; wherein X represents a halogen atom), formyl (—C(═O)—H), isocyano, isocyanate; thiocyanate or isothiocyanate, hydroxyl, nitro, CF₃, Cl, Br, F, crosslinkable groups or optionally substituted or unsubstituted aromatic or heteroaromatic ring system containing 5 to 40 ring atoms, or aryloxy or heteroaryloxy containing 5 to 40 ring atoms; wherein when one or some of R² exist simultaneously, they exist independently or form a monocyclic or polycyclic aliphatic or aromatic ring system with each other and/or with the groups.

6. The formulation for printing electronic device of claim 1, wherein the organic solvent based on alicyclic structure and having general formula (I) is selected from the group consisting of tetralin, cyclohexylbenzene, decahydronaphthalene, 2-phenoxytetrahydrofuran, 1,1′-bicyclohexyl, butyl cyclohexane, ethyl abietate, benzyl abietate, ethylene glycol carbonate, styrene oxide, isophorone, 3,3,5-trimethylcyclohexanone, cycloheptanone, fenchone, 1-tetralone, 2-tetralone, 2-(phenylepoxy)tetralone, 6-(methoxy)tetralone, γ-butyrolactone, γ-valerolactone, 6-hexanolactone, N,N-diethylcyclohexylamine, sulfolane, 2,4-dimethylsulfone, and any combination thereof.

7. The formulation for printing electronic device of claim 1, wherein the solvent system is a mixture further comprising at least one other organic solvent, and the organic solvent based on alicyclic structure and having general formula (I) accounts for 50% or more of a total weight of the mixed solvent.

8. The formulation for printing electronic device of claim 1, wherein the functional material is an inorganic nanomaterial.

9. The formulation for printing electronic device of claim 1, wherein the functional material is a quantum dot material.

10. The formulation for printing electronic device of claim 1, wherein the functional material is a luminescent quantum dot material having a light emitting wavelength in a range from 380 nm to 2500 nm.

11. The formulation for printing electronic device of claim 1, comprising an inorganic functional material being a binary or multivariate semiconductor compounds selected from the group consisting of Group IV, Group II-VI, Group II-V, Group III-V, Group III-VI, Group IV-VI, Group I-III-VI, Group II-IV-VI, Group II-IV-V of the Periodic Table of the Elements, and any combination thereof.

12. The formulation for printing electronic device of claim 1, wherein the functional material is a perovskite nanoparticle material.

13. The formulation for printing electronic device of claim 1, wherein the functional material is selected from the group consisting of a luminescent perovskite nanomaterial, a metal nanoparticle material, a metal oxide nanoparticle material, and any combination thereof.

14. The formulation for printing electronic device of claim 1, wherein the functional material is an organic functional material.

15. The formulation for printing electronic device of claim 14, wherein the organic functional material is selected from the group consisting of a hole injection material, a hole transport material, an electron transport material, an electron injection material, an electron blocking material, a hole blocking material, an emitter, a host material, an organic dye, and any combination thereof.

16. The formulation for printing electronic device of claim 15, wherein the organic functional material comprises at least one host material and at least one emitter.

17. The formulation for printing electronic device of claim 1, wherein the functional material accounts for 0.3%˜30% of a total weight of the formulation, and the organic solvent accounts for 70%˜99.7% of the total weight of the formulation.

18. An electronic device comprising a functional layer printed or coated by the formulation for printing electronic device of claim 1, wherein the organic solvent based on alicyclic structure and having general formula (I) contained in the formulation is capable of being evaporated from the solvent system to form the functional material film.

19. The electronic device of claim 18, wherein the electronic device is selected from the group consisting of a quantum dot light emitting diode (QLED), a quantum dot photovoltaic cell (QPV), a quantum dot light emitting electrochemical cell (QLEEC), a quantum dot field effect transistor (QFET), a quantum dot light emitting field effect transistor, a quantum dot laser, a quantum dot sensor, an organic light emitting diode (OLED), an organic photovoltaic cell (OPV), an organic light emitting electrochemical cell (OLEEC), an organic field effect transistor (OFET), an organic light emitting field effect transistor, and an organic sensor.

20. A method for preparing a functional material film comprising disposing the formulation for printing electronic device of claim 1 on a substrate by a printing or coating method, wherein the printing or coating method is selected from the group consisting of inkjet printing, nozzle printing, typographic printing, screen printing, dip coating, spin coating, blade coating, roller printing, torsion roller printing, lithographic printing, flexographic printing, rotary printing, spray coating, brush coating, pad printing, and slot die coating.
